(19) United States
(12) Patent Application Publication
(10) Pub. No.: US 2026/0026163 A1
(43) Pub. Date: Jan. 22, 2026

(54) DISPLAY DEVICE AND METHOD FOR FABRICATING THE SAME, AND TILED DISPLAY DEVICE INCLUDING A PLURALITY OF DISPLAY DEVICES

(71) Applicant: Samsung Display Co., LTD., Yongin-si (KR)

(72) Inventors: Jung An LEE, Yongin-si (KR); Bo Bae LEE, Yongin-si (KR); Yu Jin LEE, Yongin-si (KR); Sun PARK, Yongin-si (KR)

(21) Appl. No.: 19/078,059

(22) Filed: Mar. 12, 2025

(30) Foreign Application Priority Data
Jul. 18, 2024 (KR) 10-2024-0094951

(51) Int. Cl. H10H 29/49; H10H 29/41

(52) U.S. Cl. CPC H10H 29/49; H10H 29/41

(57) ABSTRACT

An electronic device according to one or more embodiments includes a display device including a substrate including a sub-pixel area, a first pad electrode and a second pad electrode above a first surface of the substrate, and spaced apart from each other in the sub-pixel area, an insulating layer between the first pad electrode and the second pad electrode, covering an end of the first pad electrode facing the second pad electrode, covering an end of the second pad electrode facing the first pad electrode, and including an organic layer, and an inorganic layer above the organic layer, and a light-emitting element above the first pad electrode, the second pad electrode, and the insulating layer, and electrically connected between the first pad electrode and the second pad electrode.

### CROSS-REFERENCE TO RELATED APPLICATION

The present application claims priority to, and the benefit of, Korean Patent Application No. 10-2024-0094951, filed on Jul. 18, 2024, in the Korean Intellectual Property Office, the entire disclosure of which is incorporated herein by reference.

### BACKGROUND

### 1. Field

The present disclosure relates to a display device, to a method for fabricating the same, and to a tiled display device including a plurality of display devices.

### 2. Description of the Related Art

As the information society develops, the demand for display devices for displaying images has increased and diversified. Accordingly, various types of display devices including light-emitting display devices have been developed.

### SUMMARY

Aspects of the present disclosure provide a display device capable of reducing or preventing the likelihood of a short-circuit defect between a first pad electrode and a second pad electrode connected to a light-emitting element, a method for fabricating the same, and a tiled display device including a plurality of display devices.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided an electronic device comprising a display device including a substrate including a sub-pixel area, a first pad electrode and a second pad electrode above a first surface of the substrate, and spaced apart from each other in the sub-pixel area, an insulating layer between the first pad electrode and the second pad electrode, covering an end of the first pad electrode facing the second pad electrode, covering an end of the second pad electrode facing the first pad electrode, and including an organic layer, and an inorganic layer above the organic layer, and a light-emitting element above the first pad electrode, the second pad electrode, and the insulating layer, and electrically connected between the first pad electrode and the second pad electrode.

The organic layer may cover the end of the first pad electrode and the end of the second pad electrode, wherein the inorganic layer completely covers the organic layer.

The electronic may further include a planarization layer at an edge of the sub-pixel area above the first surface of the substrate, and defining an opening at an area where the light-emitting element is located, and a passivation layer above the planarization layer.

The planarization layer and the passivation layer may cover another end of the first pad electrode, and another end of the second pad electrode.

The organic layer and the planarization layer may include a same organic insulating material, wherein a height of the organic layer is lower than a height of the planarization layer.

The inorganic layer and the passivation layer may include a same inorganic insulating material.

The inorganic layer may completely cover the organic layer, wherein the passivation layer completely covers the planarization layer.

The light-emitting element may include a first portion above the first pad electrode, a second portion above the second pad electrode, and a third portion above the insulating layer, and connecting the first portion and the second portion.

A thickness of the third portion may be less than a thickness of the first portion and less than a thickness of the second portion.

The electronic device may further include a back-side line below a second surface of the substrate.

According to an aspect of the present disclosure, there is provided a method for fabricating a display device, the method including arranging a first pad electrode and a second pad electrode in a sub-pixel area above a substrate, arranging an insulating layer covering an end of the first pad electrode and an end of the second pad electrode, and including an organic layer between the first pad electrode and the second pad electrode, and an inorganic layer above the organic layer, and arranging a light-emitting element above the first pad electrode, the second pad electrode, and the insulating layer so as to be electrically connected to the first pad electrode and the second pad electrode.

The organic layer may cover the end of the first pad electrode and the end of the second pad electrode.

The method may further include arranging a planarization layer at an edge of the sub-pixel area.

The organic layer may be at a lower height than the planarization layer.

The method may further include arranging a passivation layer covering the planarization layer.

According to an aspect of the present disclosure, there is provided a tiled display device including display devices, at least one of the display devices including a substrate including a sub-pixel area, a first pad electrode and a second pad electrode above a first surface of the substrate, and spaced apart from each other in the sub-pixel area, an insulating layer between the first pad electrode and the second pad electrode, covering an end of the first pad electrode facing the second pad electrode, covering an end of the second pad electrode facing the first pad electrode, and including an organic layer, and an inorganic layer above the organic layer, and a light-emitting element above the first pad electrode, the second pad electrode, and the insulating layer, and electrically connected between the first pad electrode and the second pad electrode.

The organic layer may cover the end of the first pad electrode and the end of the second pad electrode, wherein the inorganic layer completely covers the organic layer.

The at least one of the display devices may further include a planarization layer at an edge of the sub-pixel area above the first surface of the substrate, and defining an opening at an area where the light-emitting element is located, and a passivation layer above the planarization layer.

The organic layer and the planarization layer may include a same organic insulating material, wherein a height of the organic layer is lower than a height of the planarization layer.

The at least one of the display devices may further include a back-side line below a second surface of the substrate.

With a display device and a method for fabricating the same, and a tiled display device including a plurality of display devices according to embodiments, by arranging an insulating layer including an organic layer between a first pad electrode and a second pad electrode, it is possible to secure insulation between the first pad electrode and the second pad electrode, and to reduce or prevent the likelihood of a short-circuit defect between the first pad electrode and the second pad electrode. Accordingly, it is possible to reduce or prevent the likelihood of a defect of the display device, and to improve a yield of the display device.

However, aspects according to the embodiments of the present disclosure are not limited to those above, and various other aspects are incorporated herein.

### BRIEF DESCRIPTION OF THE DRAWINGS

The above and other aspects of the present disclosure will become more apparent by describing in detail embodiments thereof with reference to the attached drawings, in which:

FIG. 1 is a perspective view illustrating a display device according to one or more embodiments;

FIG. 2 is a perspective view illustrating the display device according to one or more embodiments;

FIG. 3 is a plan view illustrating a pixel according to one or more embodiments;

FIG. 4 is a plan view illustrating a pixel according to one or more embodiments;

FIG. 5 is a plan view illustrating a portion of a display panel according to one or more embodiments;

FIG. 6 is a rear view illustrating a portion of the display panel according to one or more embodiments;

FIG. 7 is a cross-sectional view illustrating the display panel according to one or more embodiments;

FIG. 8 is a cross-sectional view illustrating the display panel according to one or more embodiments;

FIG. 9 is a cross-sectional view illustrating a display panel according to one or more embodiments;

FIG. 10 is a flowchart illustrating a method for fabricating the display device according to one or more embodiments;

FIGS. 11 to 15 are cross-sectional views illustrating a method for fabricating the display device according to one or more embodiments;

FIG. 16 is a plan view illustrating a tiled display device according to one or more embodiments;

FIG. 17 is a plan view illustrating a tiled display device according to one or more embodiments;

FIG. 18 is a plan view illustrating a seam portion of the tiled display device according to one or more embodiments in detail; and

FIG. 19 is a cross-sectional view illustrating the tiled display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

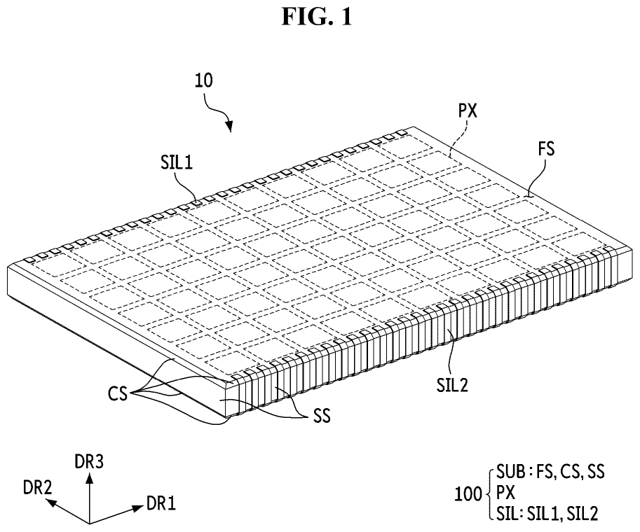

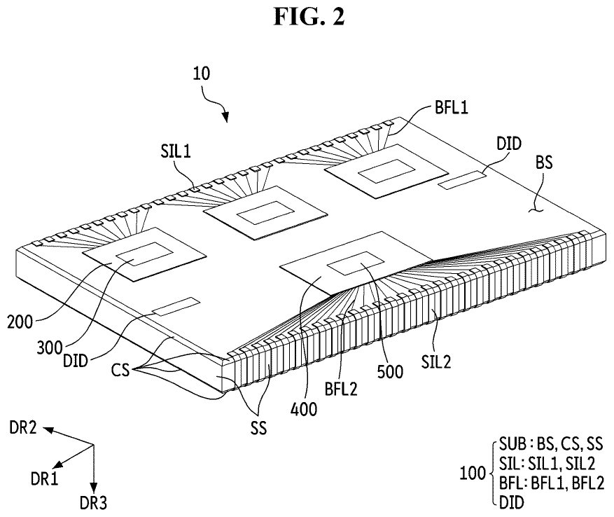

FIG. 1 is a perspective view illustrating a display device according to one or more embodiments. FIG. 2 is a perspective view illustrating the display device according to one or more embodiments. For example, FIGS. 1 and 2 are perspective views illustrating a front surface and a back surface of the display device 10, respectively.

Referring to FIGS. 1 and 2, a display device 10 according to one or more embodiments is a device that displays a moving image or a still image, and may be used as a display screen of various electronic devices such as televisions, laptop computers, monitors, billboards, and the Internet of Things (IoT) devices as well as portable electronic devices such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs). For example, at least one of the electronic devices described above or another electronic device may include the display device 10 according to at least one of embodiments disclosed herein.

The display device 10 may include a display panel 100, a first circuit board 200, a source driver 300, a second circuit board 400, and a power supply (e.g., power supply unit) 500. In one or more embodiments, the display device 10 may include a plurality of first circuit boards 200 and a plurality of source drivers 300. In one or more embodiments, the first circuit boards 200, the source drivers 300, the second circuit board 400, and the power supply 500 may be located on a back surface of the display panel 100.

The display panel 100 may include a substrate SUB, pixels PX, side lines SIL, and back-side lines BFL. In one or more embodiments, the display panel 100 may further include device identifiers DID.

The substrate SUB may include a first surface FS, a second surface BS, and side surfaces SS. The first surface FS and the second surface BS of the substrate SUB may oppose each other. For example, the first surface FS may be a front surface of the substrate SUB, and the second surface BS may be a back surface of the substrate SUB. In one or more embodiments, the substrate SUB may further include chamfered surfaces CS located between the first surface FS and the second surface BS, and the side surfaces SS.

In one or more embodiments, the substrate SUB may have a substantially rectangular shape on a plane defined by a first direction DR1 and by a second direction DR2. In one or more embodiments, the first direction DR1 may be a transverse direction or a long-side direction of the substrate SUB, and the second direction DR2 may be a longitudinal direction or a short-side direction of the substrate SUB. The substrate SUB may have a thickness in a third direction DR3 crossing (e.g., orthogonal to) the first direction DR1 and the second direction DR2.

When the substrate SUB has the substantially rectangular shape in plan view, the substrate SUB may include four side surfaces SS and eight chamfered surfaces CS located between each of the first surface FS and the second surface BS and the four side surfaces SS of the substrate SUB. The chamfered surfaces CS may refer to surfaces obliquely chamfered at boundary portions between each of the first surface FS and the second surface BS of the substrate SUB and the side surfaces SS to reduce or prevent chipping defects from occurring in the side lines SIL. Due to the chamfered surfaces CS, a bending angle of each of the side lines SIL may become gentle. Accordingly, it is possible to reduce or prevent chipping or cracks from occurring in the side lines SIL.

A shape of the substrate SUB is not limited to the above. For example, the substrate SUB may have various shapes according to embodiments.

The pixels PX may be located on the first surface FS of the substrate SUB to display an image. The pixels PX may be arranged in a matrix form in the first direction DR1 and the second direction DR2, but an arrangement form of the pixels PX is not limited thereto.

The side lines SIL may include first side lines SIL1 and second side lines SIL2 located on different side surfaces of the substrate SUB. As an example, the side lines SIL may include the first side lines SIL1 located on one side surface SS of the substrate SUB positioned at an upper end of the substrate SUB in the second direction DR2, and the second side lines SIL2 located on another side surface SS of the substrate SUB positioned at a lower end of the substrate SUB in the second direction DR2.

For example, the first side lines SIL1 may be located on the first surface FS, the second surface BS, any one side surface SS (e.g., an upper side surface), and two chamfered surfaces CS located between any one side surface SS and each of the first surface FS and the second surface BS of the substrate SUB. Also, for example, the second side lines SIL2 may be located on the first surface FS, the second surface BS, any one side surface SS (e.g., a lower side surface), and two chamfered surfaces CS located between any one side surface SS and each of the first surface FS and the second surface BS of the substrate SUB.

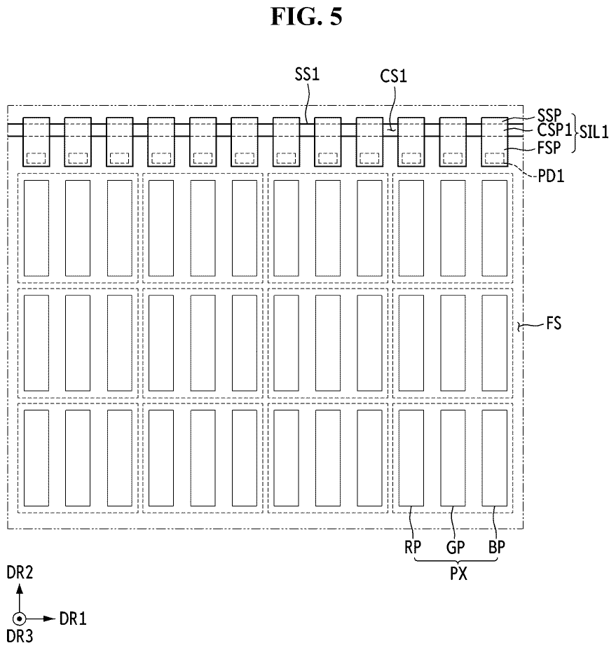

The first side lines SIL1 may connect upper pads (e.g., first pads PD1 of FIG. 5) located on the first surface FS of the substrate SUB respectively to first back-side lines BFL1 (e.g., first back surface fan-out lines) located on the second surface BS of the substrate SUB. The second side lines SIL2 may connect lower pads located on the first surface FS of the substrate SUB respectively to second back-side lines BFL2 (e.g., second back surface fan-out lines) located on the second surface BS of the substrate SUB. The upper pads and the lower pads located on the first surface FS of the substrate SUB may correspond to front surface pads of the display panel 100. In one or more embodiments, the upper pads located on the first surface FS of the substrate SUB may be connected to data lines connected to the pixels PX. In one or more embodiments, the lower pads located on the first surface FS of the substrate SUB may be connected to power lines (e.g., a first power, a second power line, etc.) connected to the pixels PX. In describing embodiments, the term “connection” may include the meaning of an electrical connection and/or a physical connection.

One or more embodiments in which the number of first side lines SIL1 and the number of second side lines SIL2 are substantially the same as or similar to each other has been disclosed in FIGS. 1 and 2, but embodiments are not limited thereto. As an example, the number of second side lines SIL2 may be less than the number of first side lines SIL1. Alternatively, some of the second side lines SIL2, for example, a plurality of second side lines SIL2 to which the same driving voltage is applied, may be formed integrally with each other, and accordingly, a single line having a greater width may be configured.

The back-side lines BFL may be located on the second surface BS of the substrate SUB, and may be connected to the side lines SIL. For example, the back-side lines BFL may include first back-side lines BFL1 respectively connected to the first side lines SIL1 and second back-side lines BFL2 respectively connected to the second side lines SIL2. In one or more embodiments, the first back-side lines BFL1 may connect the first side lines SIL1 to the first circuit boards 200, and the second back-side lines BFL2 may connect the second side lines SIL2 to the second circuit board 400.

Each of the device identifiers DID may be an identifier, such as an identification number assigned to each of the display devices 10, to distinguish the display devices 10 from each other. The device identifiers DID may be located on the second surface BS of the substrate SUB. The device identifiers DID may be spaced apart from the side lines SIL, the back-side lines BFL, the first circuit boards 200, and the second circuit board 400. As an example, the device identifiers DID may be in a state in which they are electrically floated.

One or more embodiments in which the display device 10 includes two device identifiers DID has been disclosed in FIG. 2, but the number of device identifiers DID is not limited thereto. For example, the display device 10 may include only one device identifier DID, or three or more device identifiers DID.

In one or more embodiments, the device identifiers DID may be back surface patterns formed by the same process as the back-side lines BFL using the same material as the back-side lines BFL. In one or more embodiments, a back surface metal layer including the back-side lines BFL and the device identifiers DID may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

The first circuit boards 200 may be located on the second surface BS of the substrate SUB. In one or more embodiments, each of the first circuit boards 200 may be connected to the first back-side lines BFL1 using a conductive adhesive member, such as an anisotropic conductive film. The first circuit boards 200 may be electrically connected to the first side lines SIL1 through the first back-side lines BFL1. Each of the first circuit boards 200 may be a flexible printed circuit board, a printed circuit board, or a flexible film.

The source drivers 300 may generate data voltages, and may supply the data voltages to the data lines through the first circuit boards 200, the first back-side lines BFL1, and the first side lines SIL1. Each of the source drivers 300 may be formed as an integrated circuit (IC) and attached onto the first circuit board 200 corresponding thereto. Alternatively, each of the source drivers 300 may be directly attached onto the second surface BS of the substrate SUB in a chip-on-glass (COG) manner. In this case, the display device 10 may not include the first circuit boards 200, and the source drivers 300 may supply the data voltages to the data lines through the first back-side lines BFL1 and the first side lines SIL1.

The second circuit board 400 may be located on the second surface BS of the substrate SUB. In one or more embodiments, the second circuit board 400 may be connected to the second back-side lines BFL2 using a conductive adhesive member. The second circuit board 400 may be electrically connected to the second side lines SIL2 through the second back-side lines BFL2. The second circuit board 400 may be a flexible printed circuit board, a printed circuit board, or a flexible film.

The power supply 500 may generate driving voltages required for driving the display panel 100, and may supply the driving voltages to the respective power lines through the second circuit board 400, the second back-side lines BFL2, and the second side lines SIL2. For example, the power supply 500 may generate a first driving voltage, and may supply the first driving voltage to a first power line (e.g., a pixel power line) through the second circuit board 400, a plurality of second back-side lines BFL2, and the plurality of second side lines SIL2. In addition, the power supply 500 may generate a second driving voltage, and may supply the second driving voltage to a second power line (e.g., a common power line) through the second circuit board 400, the plurality of second back-side lines BFL2, and the plurality of second side lines SIL2. The first driving voltage and the second driving voltage supplied to the first power line and the second power line, respectively, may be transferred to the pixels PX.

The power supply 500 may be formed as an integrated circuit (IC) and attached onto the second circuit board 400. Alternatively, the power supply 500 may be directly attached onto the second surface BS of the substrate SUB in a COG manner. In this case, the display device 10 may not include the second circuit board 400, and the power supply 500 may supply the first driving voltage and the second driving voltage to the first power line and the second power line, respectively, through the second back-side lines BFL2 and the second side lines SIL2.

As illustrated in FIGS. 1 and 2, the pixels PX, signal lines, and power lines located on the first surface FS of the substrate SUB may be connected to the back-side lines BFL, the first circuit boards 200, the source drivers 300, the second circuit board 400, the power supply 500, and the like, located on the second surface BS of the substrate SUB using the side lines SIL. Accordingly, a flexible film bent along the side surface SS or the like of the substrate SUB may be removed or omitted, and a bezel-less display device may be implemented.

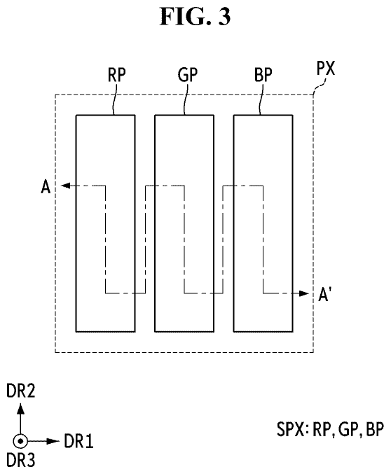

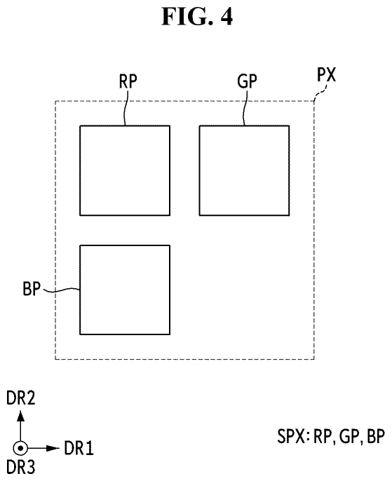

FIG. 3 is a plan view illustrating a pixel according to one or more embodiments. FIG. 4 is a plan view illustrating a pixel according to one or more embodiments.

FIGS. 3 and 4 illustrate different embodiments in relation to an arrangement structure of sub-pixels SPX included in the pixel PX. In addition, FIGS. 3 and 4 schematically illustrate pixels PX according to respective embodiments based on emission areas of sub-pixels SPX (e.g., areas where respective light-emitting elements are attached).

Referring to FIGS. 3 and 4, the pixel PX may include a plurality of sub-pixels SPX. Embodiments in which each pixel PX includes three sub-pixels SPX including a first sub-pixel RP, a second sub-pixel GP, and a third sub-pixel BP have been disclosed in FIGS. 3 and 4, but the number, a ratio, a type, and the like, of sub-pixels SPX constituting each pixel PX may be changed depending on embodiments.

The sub-pixels SPX may be connected to signal lines and power lines. For example, each of the sub-pixels SPX may be connected to at least one gate line to which at least one gate signal including a scan signal is applied, a data line to which a data voltage is applied, a first power line to which a first driving voltage (e.g., a high-potential pixel voltage) is applied, a second power line to which a second driving voltage (e.g., a low-potential pixel voltage or a common voltage) is applied, and the like. Types, the numbers, and the like, of signal lines and power lines connected to the sub-pixels SPX may be changed depending on structures, operating methods, or the like, of the sub-pixels SPX.

Each of the sub-pixels SPX may have a quadrangular shape or another shape in plan view. As an example, each of the first sub-pixel RP, the second sub-pixel GP, and the third sub-pixel BP may have a rectangular shape or a square shape in plan view as illustrated in FIGS. 3 and 4 or have a rhombic shape or another shape in plan view.

The sub-pixels SPX of each pixel PX may be sequentially located along the first direction DR1 or may be arranged in a corresponding form along the first direction DR1, the second direction DR2, and the like. As an example, as illustrated in FIG. 3, the first sub-pixel RP, the second sub-pixel GP, and the third sub-pixel BP may be sequentially located along the first direction DR1. Alternatively, as illustrated in FIG. 4, the first sub-pixel RP and the second sub-pixel GP may neighbor to each other in the first direction DR1, and the first sub-pixel RP and the third sub-pixel BP may neighbor to each other in the second direction DR2. The second sub-pixel GP and the third sub-pixel BP may be located in a diagonal direction within the pixel PX. The sub-pixels SPX may also be arranged in each pixel area in another arrangement form.

The sub-pixels SPX (or the emission areas of the sub-pixels SPX) may have substantially the same size or different sizes. As an example, the first sub-pixel RP, the second sub-pixel GP, and the third sub-pixel BP may have substantially the same size or similar sizes, as illustrated in FIGS. 3 and 4. Alternatively, at least two of first sub-pixel RP, the second sub-pixel GP, and the third sub-pixel BP may have different sizes, depending on light efficiency, white balance, or the like, of the sub-pixels SPX.

In one or more embodiments, the sub-pixels SPX may emit light of different colors. For example, the first sub-pixel RP may emit light of a first color (e.g., red light of a wavelength band of approximately 600 nm to approximately 750 nm), the second sub-pixel GP may emit light of a second color (e.g., green light of a wavelength band of approximately 480 nm to approximately 560 nm), and the third sub-pixel BP may emit light of a third color (e.g., blue light of a wavelength band of approximately 370 nm to approximately 460 nm). However, embodiments are not limited thereto. For example, each pixel PX may also include at least two sub-pixels SPX that emit light of the same color.

Each of the sub-pixels SPX may include a light-emitting unit including at least one light-emitting element. In one or more embodiments, each of the sub-pixels SPX may further include a pixel circuit including circuit elements (e.g., a plurality of thin film transistors and at least one capacitor) for driving or controlling the light-emitting unit. The pixel circuit of each sub-pixel SPX may be electrically connected to the light-emitting unit of the corresponding sub-pixel SPX. The light-emitting unit and the pixel circuit of each sub-pixel SPX may or may not overlap each other.

In one or more embodiments, each of the sub-pixels SPX may include an inorganic light-emitting element. For example, each of the first sub-pixel RP, the second sub-pixel GP, and the third sub-pixel BP may include at least one inorganic light-emitting element including an inorganic semiconductor. In one or more embodiments, the inorganic light-emitting element may be a micro light-emitting diode (hereinafter referred to as a “micro LED”) of which each of a length in the first direction DR1, a length in the second direction DR2, and a length (e.g., a thickness or a height) in the third direction DR3 is several micrometers (μm) to several hundreds of micrometers (μm), but is not limited thereto. For example, a type, a material, a structure, a size, and the like, of the light-emitting element constituting the light-emitting unit of each of the sub-pixels SPX may be changed depending on embodiments.

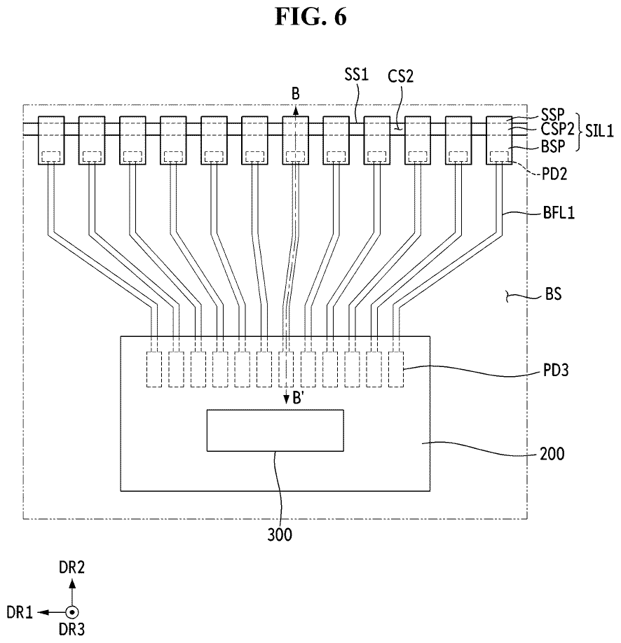

FIG. 5 is a plan view illustrating a portion of a display panel according to one or more embodiments. FIG. 6 is a rear view illustrating a portion of the display panel according to one or more embodiments. For example, FIGS. 5 and 6 illustrate one or more embodiments of a portion of an upper edge of the display panel 100 illustrated in FIGS. 1 and 2.

Referring to FIGS. 5 and 6, the display panel 100 may include first pads PD1, second pads PD2, third pads PD3, the first side lines SIL1, and the first back-side lines BFL1.

The first pads PD1 may be front surface pads located on the first surface FS of the substrate SUB. The first pads PD1 may be located on an edge of a first side (e.g., an edge of an upper side) of the first surface FS of the substrate SUB. The first pads PD1 may be arrange in the first direction DR1.

The second pads PD2 may be back surface pads located on the second surface BS of the substrate SUB. The second pads PD2 may be located on an edge of a first side (e.g., an edge of an upper side) of the second surface BS of the substrate SUB. The second pads PD2 may be arranged in the first direction DR1.

The third pads PD3 may be back surface pads located on the second surface BS of the substrate SUB. The third pads PD3 may be located closer to the center of the second surface BS of the substrate SUB than the second pads PD2 are. The third pads PD3 may be arranged in the first direction DR1. To connect more third pads PAD3 to the first circuit board 200, an interval between the third pads PAD3 neighboring to each other in the first direction DR1 may be less than an interval between the second pads PAD2 neighboring to each other in the first direction DR1.

Each of the first back-side lines BFL1 connects a pair of second pad PD2 and third pad PD3 to each other. When the interval between the second pads PAD2 neighboring to each other in the first direction DR1 and the interval between the third pads PAD3 neighboring to each other in the first direction DR1 are different from each other, one or more of the first back-side lines BFL1 may be bent at least once. In one or more embodiments, each of the first back-side lines BFL1 may be formed integrally with the second pad PD2 and the third pad PD3 (or portions of the second pad PD2 and the third pad PD3). Each of the second pad PAD2, the third pad PAD3, and the first back-side line BFL1 may be formed as a single layer or multiple layers including any one of molybdenum (Mo), aluminum (Al), chromium (Cr), gold (Au), titanium (Ti), nickel (Ni), neodymium (Nd), or copper (Cu), or alloys thereof.

Each of the first side lines SIL1 may include first, second, third, fourth, and fifth portions FSP, CSP1, SSP, CSP2, and BSP.

The first portion FSP corresponds to a front surface portion located on the first surface FS of the substrate SUB. The first portion FSP may be located on the first pad PD1, and may completely cover the first pad PD1. The first portion FSP may be connected to the first pad PD1.

The second portion CSP1 corresponds to a first chamfered portion located on a first chamfered surface CS1 of the substrate SUB. The first chamfered surface CS1 of the substrate SUB is one of the chamfered surfaces CS of the substrate SUB, and may be a chamfered surface between a first side surface SS1 and the first surface FS of the substrate SUB. The first side surface SS1 of the substrate SUB is one of the side surfaces SS of the substrate SUB, and may be a side surface (e.g., an upper side surface of FIGS. 1 and 2) on which the first side lines SIL1 are located. The second portion CSP1 may be located between the first portion FSP and the third portion SSP.

The third portion SSP corresponds to a side surface portion located on the first side surface SS1 of the substrate SUB. The third portion SSP may be located between the second portion CSP1 and the fourth portion CSP2.

The fourth portion CSP2 corresponds to a second chamfered portion located on a second chamfered surface CS2 of the substrate SUB. The second chamfered surface CS2 of the substrate SUB is one of the chamfered surfaces CS of the substrate SUB, and may be a chamfered surface between the first side surface SS1 and the second surface BS of the substrate SUB. The fourth portion CSP2 may be located between the third portion SSP and the fifth portion BSP.

The fifth portion BSP corresponds to a back surface portion located on the second surface BS of the substrate SUB. The fifth portion BSP may be located on the second pad PD2, and may completely cover the second pad PD2. The fifth portion BSP may be connected to the second pad PD2.

In one or more embodiments, the first side line SIL1 may include a metal powder including metal particles, such as silver (Ag) particles and copper (Cu) particles and a polymer, such as an acrylic resin or an epoxy resin. The metal powder may allow the first side line SIL1 to have conductivity, and the polymer may serve as a binder binding the metal particles to each other.

In one or more embodiments, the first side line SIL1 may be formed by printing a metal paste including metal particles, a monomer, and a solvent on the substrate SUB using a silicon pad and then sintering the metal paste using a laser. In a sintering process of the first side line SIL1, the metal particles are in close contact and aggregated with each other while the monomer is converted into a polymer by heat of the laser, such that resistance of the first side line SIL1 may be lowered. In one or more embodiments, the first side line SIL1 and the second side line SIL2 of FIGS. 1 and 2 may be formed in the same manner using the same material.

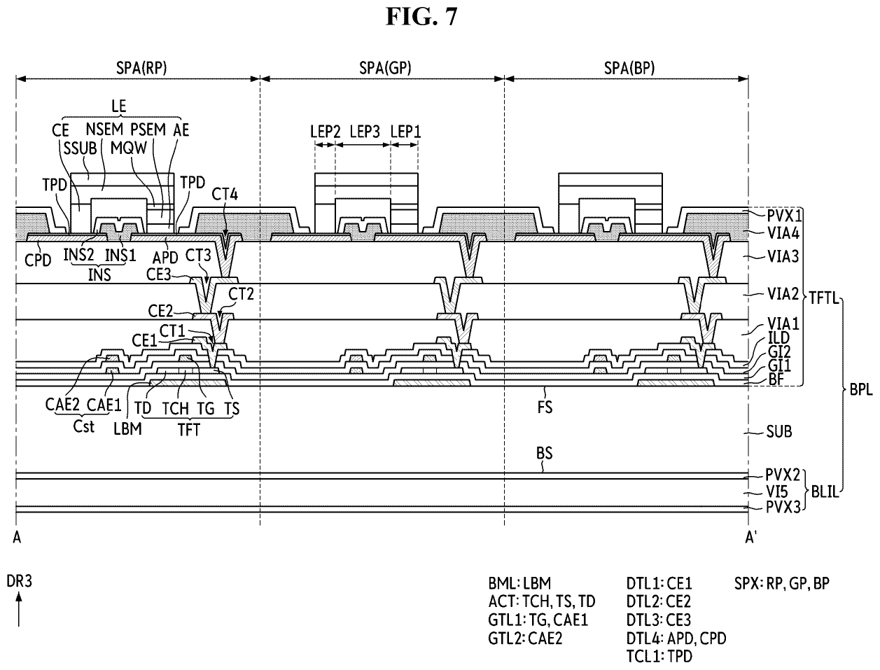

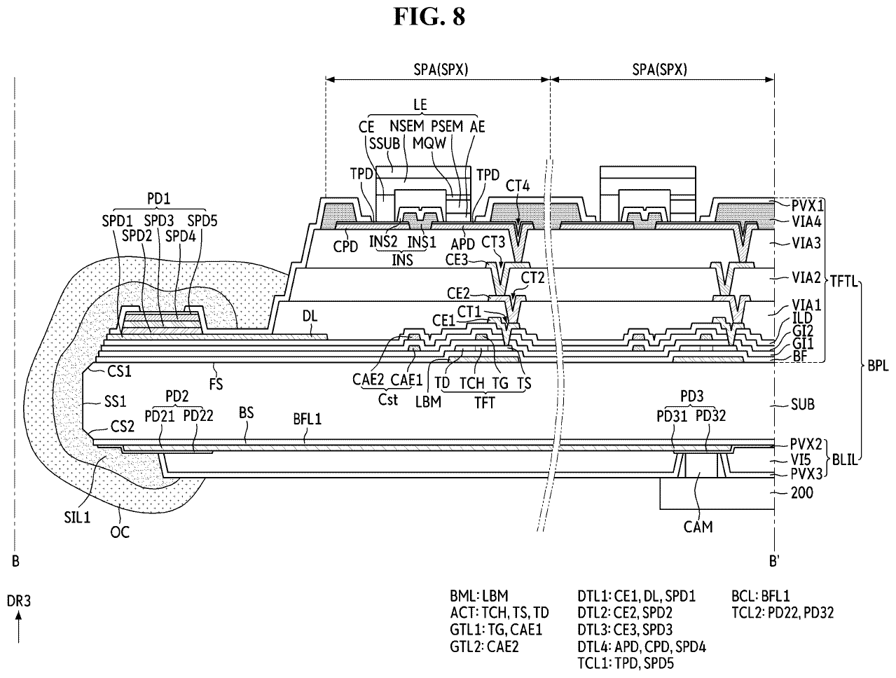

FIG. 7 is a cross-sectional view illustrating the display panel according to one or more embodiments. FIG. 8 is a cross-sectional view illustrating the display panel according to one or more embodiments. For example, FIG. 7 illustrates one or more embodiments of a cross section of a portion of the display panel 100 taken along the line A-A′ of FIG. 3, and FIG. 8 illustrates one or more embodiments of a cross section of a portion of the display panel 100 taken along the line B-B′ of FIG. 6.

Referring to FIGS. 1 to 8, the display panel 100 may include a backplane layer BPL, and light-emitting elements LE located on a front surface of the backplane layer BPL. The light-emitting elements LE may be located in sub-pixel areas SPA where the respective sub-pixels SPX are located. For example, at least one light-emitting element LE may be located in each sub-pixel area SPA.

The first circuit board 200 and the like may be located on a back surface of the backplane layer BPL. The side lines SIL including the first side lines SIL1, and an overcoat layer OC covering the side lines SIL, may be located on a side surface of the backplane layer BPL.

The backplane layer BPL may include the substrate SUB, a thin film transistor layer TFTL, and a back-side line layer BLIL. The thin film transistor layer TFTL may be located on the first surface FS of the substrate SUB, and the back-side line layer BLIL may be located on the second surface BS of the substrate SUB.

The substrate SUB may be a base substrate or a base member for supporting the display device 10. The substrate SUB may be a rigid substrate made of glass, but is not limited thereto. For example, the substrate SUB may be a flexible substrate that may be bent, folded, or rolled. In this case, the substrate SUB may include an insulating material, such as a polymer resin, for example, polyimide PI.

The substrate SUB and the display device 10 including the substrate SUB may include the sub-pixel areas SPA. A pixel circuit and a light-emitting element LE of a corresponding sub-pixel SPX may be located in each sub-pixel area SPA.

The thin film transistor layer TFTL may include circuit elements constituting the pixel circuit of each of the sub-pixels SPX and the front surface pads including the first pads PD1. In FIG. 7, one thin film transistor TFT and a capacitor Cst have been illustrated as a representative of the circuit elements that may be located in each sub-pixel area SPA. The thin film transistor layer TFTL may further include front surface lines connected to the sub-pixels SPX.

The thin film transistor layer TFTL may include at least one semiconductor layer and a plurality of conductive layers. For example, the thin film transistor layer TFTL may include an active layer ACT, a first gate layer GTL1, a second gate layer GTL2, a first data metal layer DTL1, a second data metal layer DTL2, a third data metal layer DTL3, a fourth data metal layer DTL4, and a first transparent conductive layer TCL1. In one or more embodiments, the thin film transistor layer TFTL may further include a bottom metal layer BML.

In addition, the thin film transistor layer TFTL may include a plurality of insulating layers. For example, the thin film transistor layer TFTL may include a buffer layer BF, a first gate-insulating layer GI1, a second gate-insulating layer GI2, an interlayer insulating layer ILD, a first planarization layer VIA1, a second planarization layer VIA2, a third planarization layer VIA3, a fourth planarization layer VIA4 (e.g., a planarization layer in the claims), and a first passivation layer PVX1 (e.g., a passivation layer in the claims).

The bottom metal layer BML may be located on (as used herein, “located on” may mean “above” or “below”) the first surface FS of the substrate SUB. The bottom metal layer BML may include an opaque material capable of blocking light. For example, the bottom metal layer BML may include a conductive material, such as a metal.

The bottom metal layer BML may include a light-blocking pattern LBM. In one or more embodiments, the light-blocking pattern LBM may be located below an active layer ACT of at least one thin film transistor TFT located in each sub-pixel area SPA.

The buffer layer BF may be located on the bottom metal layer BML. The buffer layer BF may be a film for reducing or preventing permeation of air or moisture. The buffer layer BF may include an inorganic insulating material. In one or more embodiments, the buffer layer BF may include a plurality of inorganic layers that are alternately stacked. As an example, the buffer layer BF may be formed as multiple films in which one or more inorganic layers of a silicon nitride layer, a silicon oxynitride layer, a silicon oxide layer, a titanium oxide layer, or an aluminum oxide layer are alternately stacked. The buffer layer BF may be omitted.

The active layer ACT may be located on the buffer layer BF. The active layer ACT may include a semiconductor material. For example, the active layer ACT may include a silicon semiconductor, such as polycrystalline silicon, single crystal silicon, low-temperature polycrystalline silicon, and/or amorphous silicon, or may include an oxide semiconductor.

The active layer ACT may include a channel TCH, a first electrode TS, and a second electrode TD of the thin film transistor TFT. The channel TCH of the thin film transistor TFT may overlap a gate electrode TG of the thin film transistor TFT in the third direction DR3, which is a thickness direction of the substrate SUB. The first electrode TS of the thin film transistor TFT may be located on one side of the channel TCH, and the second electrode TD of the thin film transistor TFT may be located on the other side of the channel TCH. The first electrode TS and the second electrode TD of the thin film transistor TFT may have higher conductivity than the channel TCH. For example, the first electrode TS and the second electrode TD of the thin film transistor TFT may be regions having conductivity by doping a silicon semiconductor or an oxide semiconductor with ions or by using another method.

The first gate-insulating layer GI1 may be located on the active layer ACT. The first gate-insulating layer GI1 may include an inorganic insulating material. For example, the first gate-insulating layer GI1 may be formed as an inorganic layer, such as a silicon nitride layer, a silicon oxynitride layer, a silicon oxide layer, a titanium oxide layer, or an aluminum oxide layer.

The first gate layer GTL1 may be located on the first gate-insulating layer GI1. The first gate layer GTL1 may include the gate electrode TG of the thin film transistor TFT and a first capacitor electrode CAE1. The first gate layer GTL1 may include a conductive material. For example, the first gate layer GTL1 may be formed as a single layer or a multiple layer made of any one of molybdenum (Mo), aluminum (Al), chromium (Cr), gold (Au), titanium (Ti), nickel (Ni), neodymium (Nd), or copper (Cu), or alloys thereof.

The second gate-insulating layer GI2 may be located on the first gate layer GTL1. The second gate-insulating layer GI2 may include an inorganic insulating material. For example, the second gate-insulating layer GI2 may be formed as an inorganic layer, such as a silicon nitride layer, a silicon oxynitride layer, a silicon oxide layer, a titanium oxide layer, or an aluminum oxide layer.

The second gate layer GTL2 may be located on the second gate-insulating layer GI2. The second gate layer GTL2 may include a second capacitor electrode CAE2. The second gate layer GTL2 may include a conductive material. For example, the second gate layer GTL2 may be formed as a single layer or a multiple layer made of any one of molybdenum (Mo), aluminum (Al), chromium (Cr), gold (Au), titanium (Ti), nickel (Ni), neodymium (Nd), or copper (Cu), or alloys thereof. The first capacitor electrode CAE1 and the second capacitor electrode CAE2 may overlap each other in the third direction DR3 to form a capacitor Cst.

The interlayer insulating layer ILD may be located on the second gate layer GTL2. The interlayer insulating layer ILD may include an inorganic insulating material. For example, the interlayer insulating layer ILD may be formed as an inorganic layer, such as a silicon nitride layer, a silicon oxynitride layer, a silicon oxide layer, a titanium oxide layer, or an aluminum oxide layer.

The first data metal layer DTL1 may be located on the interlayer insulating layer ILD. The first data metal layer DTL1 may include a first connection electrode CE1, a first sub-pad SPD1, and a data line DL. The data line DL may be connected to corresponding sub-pixels SPX (e.g., first sub-pixels RP, second sub-pixels GP, or third sub-pixels BP of pixels PX located in the same column in a display area) in the display area where pixels PX are located. The data line DL may be formed integrally with the first sub-pad SPD1, but embodiments are not limited thereto. The first data metal layer DTL1 may include a conductive material. For example, the first data metal layer DTL1 may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

The first connection electrode CE1 may be connected to the first electrode TS or the second electrode TD of the thin film transistor TFT through a first contact hole CT1 penetrating through the first gate-insulating layer GI1, the second gate-insulating layer GI2, and the interlayer insulating layer ILD.

The first planarization layer VIA1 may be located on the first data metal layer DTL1. The first planarization layer VIA1 may planarize a step caused by the active layer ACT, the first gate layer GTL1, the second gate layer GTL2, and the first data metal layer DTL1. The first planarization layer VIA1 may include an organic insulating material. For example, the first planarization layer VIA1 may be formed as an organic layer made of an acrylic resin, an epoxy resin, a phenolic resin, a polyamide resin, a polyimide resin, or the like. In one or more embodiments, the display panel 100 may further include an inorganic insulating film directly covering the first planarization layer VIA1.

The first planarization layer VIA1 may be entirely located in the display area where the pixels PX are located. The first planarization layer VIA1 may be omitted from an edge portion (e.g., at least a portion of a non-display area) of the display panel 100 where the first pad PD1, the first side line SIL1, and the like, are located.

The second data metal layer DTL2 may be located on the first planarization layer VIA1. The second data metal layer DTL2 may include a second connection electrode CE2 and a second sub-pad SPD2. The second connection electrode CE2 may be connected to the first connection electrode CE1 through a second contact hole CT2 penetrating through the first planarization layer VIA1. The second data metal layer DTL2 may include a conductive material. For example, the second data metal layer DTL2 may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

The second planarization layer VIA2 may be located on the second data metal layer DTL2. The second planarization layer VIA2 may include an organic insulating material. For example, the second planarization layer VIA2 may be formed as an organic layer made of an acrylic resin, an epoxy resin, a phenolic resin, a polyamide resin, a polyimide resin, or the like. In one or more embodiments, the display panel 100 may further include an inorganic insulating film directly covering the second planarization layer VIA2.

The second planarization layer VIA2 may be entirely located in the display area. The second planarization layer VIA2 may be omitted from the edge portion of the display panel 100.

The third data metal layer DTL3 may be located on the second planarization layer VIA2. The third data metal layer DTL3 may include a third connection electrode CE3 and a third sub-pad SPD3. The third connection electrode CE3 may be connected to the second connection electrode CE2 through a third contact hole CT3 penetrating through the second planarization layer VIA2. The third data metal layer DTL3 may include a conductive material. For example, the third data metal layer DTL3 may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

The third planarization layer VIA3 may be located on the third data metal layer DTL3. The third planarization layer VIA3 may include an organic insulating material. For example, the third planarization layer VIA3 may be formed as an organic layer made of an acrylic resin, an epoxy resin, a phenolic resin, a polyamide resin, a polyimide resin, or the like. In one or more embodiments, the display panel 100 may further include an inorganic insulating film directly covering the third planarization layer VIA3.

The third planarization layer VIA3 may be entirely located in the display area. The third planarization layer VIA3 may be omitted from the edge portion of the display panel 100.

The fourth data metal layer DTL4 may be located on the third planarization layer VIA3. The fourth data metal layer DTL4 may include a first pad electrode APD, a second pad electrode CPD, and a fourth sub-pad SPD4. The first pad electrode APD and the second pad electrode CPD may be spaced apart from each other in each sub-pixel area SPA. The fourth sub-pad SPD4 may be located at the edge portion of the display panel 100 (e.g., a portion of the non-display area where the pixels PX are not located). The fourth data metal layer DTL4 may include a conductive material. For example, the fourth data metal layer DTL4 may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

In one or more embodiments, the first pad electrode APD may be an anode pad electrode connected to a first electrode AE of the light-emitting element LE, and the second pad electrode CPD may be a cathode pad electrode connected to a second electrode CE of the light-emitting element LE. The first pad electrode APD may be connected to the third connection electrode CE3 through a fourth contact hole CT4 penetrating through the third planarization layer VIA3. In one or more embodiments, the second pad electrode CPD may be connected to a second power line formed in the thin film transistor layer TFTL to receive a second driving voltage.

The first transparent conductive layer TCL1 may be located on the fourth data metal layer DTL4. The first transparent conductive layer TCL1 may include transparent electrodes TPD located on each of the first pad electrode APD and the second pad electrode CPD, and may include a fifth sub-pad SPD5. The first transparent conductive layer TCL1 may include a conductive material. For example, the first transparent conductive layer TCL1 may be made of a transparent conductive oxide, such as indium tin oxide (ITO) or indium zinc oxide (IZO). The transparent electrodes TPD may increase adhesive strength between the first pad electrode APD and the second pad electrode CPD and the light-emitting element LE.

In describing embodiments, the transparent electrodes TPD have been described as separate components from the first pad electrode APD and the second pad electrode CPD, but embodiments are not limited thereto. For example, the transparent electrodes TPD may also be considered as components included in the respective pad electrodes. As an example, the first pad electrode APD, and the transparent electrode TPD on the first pad electrode APD, may be considered as constituting a multilayer first pad electrode (e.g., an anode pad electrode). The second pad electrode CPD, and the transparent electrode TPD on the second pad electrode CPD, may be considered as constituting a multilayer second pad electrode (e.g., a cathode pad electrode). In this case, the first pad electrode APD, and the transparent electrode TPD on the first pad electrode APD, may constitute a first conductive layer and a second conductive layer of the multilayer first pad electrode, respectively. Also, the second pad electrode CPD, and the transparent electrode TPD on the second pad electrode CPD, may constitute a first conductive layer and a second conductive layer of the multilayer second pad electrode, respectively.

The first pad PD1 may be formed as multiple layers including sub-pads included in at least two conductive layers of the thin film transistor layer TFTL. For example, the first pad PD1 may include the first, second, third, fourth, and fifth sub-pads SPD1, SPD2, SPD3, SPD4, and SPD5.

The fourth planarization layer VIA4 may be located on the first transparent conductive layer TCL. The fourth planarization layer VIA4 may include an organic insulating material. For example, the fourth planarization layer VIA4 may be formed as an organic layer made of an acrylic resin, an epoxy resin, a phenolic resin, a polyamide resin, a polyimide resin, or the like. The fourth planarization layer VIA4 may also be referred to as an organic insulating film.

The fourth planarization layer VIA4 may be located in a portion of the display area. For example, the fourth planarization layer VIA4 may be located at an edge of the sub-pixel area SPA, and may be opened in an area where the light-emitting element LE is located. As an example, the fourth planarization layer VIA4 may surround the light-emitting element LE of each sub-pixel SPX in plan view.

In one or more embodiments, the fourth planarization layer VIA4 may cover at least one end of each of the first pad electrode APD and the second pad electrode CPD (e.g., a right end of the first pad electrode APD and a left end of the second pad electrode CPD in FIGS. 7 and 8). The fourth planarization layer VIA4 may expose the other portions of the first pad electrode APD and the second pad electrode CPD. The fourth planarization layer VIA4 may be omitted from the edge portion of the display panel 100 (e.g., the non-display area).

The first passivation layer PVX1 may be located on the fourth planarization layer VIA4. For example, the first passivation layer PVX1 may directly cover the fourth planarization layer VIA4.

The first passivation layer PVX1 may stably or entirely cover the fourth planarization layer VIA4. For example, the first passivation layer PVX1 may completely cover the fourth planarization layer VIA4. Accordingly, it is possible to reduce or prevent an outgassing problem that may occur in a fabrication process, or the like, of the display panel 100.

The first passivation layer PVX1 may also be located at the edge portion of the display panel 100. For example, the first passivation layer PVX1 may cover an edge of the first pad PD1 and may expose the other portion of the first pad PD1. The first passivation layer PVX1 may include an inorganic insulating material. For example, the first passivation layer PVX1 may be formed as an inorganic layer, such as a silicon nitride layer, a silicon oxynitride layer, a silicon oxide layer, a titanium oxide layer, or an aluminum oxide layer. The first passivation layer PVX1 may also be referred to as an inorganic insulating film. The first passivation layer PVX1 may be opened in an area where the light-emitting element LE is to be located to expose a portion of each of the first pad electrode APD and the second pad electrode CPD.

In embodiments, an insulating layer INS (also referred to as an “insulating pattern”) may be located between the first pad electrode APD and the second pad electrode CPD. The insulating layer INS may cover one end of the first pad electrode APD (e.g., a left end of the first pad electrode APD in FIGS. 7 and 8) facing the second pad electrode CPD, and may cover one end of the second pad electrode CPD (e.g., a right end of the second pad electrode CPD in FIGS. 7 and 8) facing the first pad electrode APD. The insulating layer INS may include an organic layer INS1, and an inorganic layer INS2 located on the organic layer INS1, and accordingly, may be formed as at least double layers.

In one or more embodiments, the insulating layer INS may be formed at a height that is lower than or equal to a maximum height set so that the light-emitting element LE may be appropriately or easily located on the first pad electrode APD and the second pad electrode CPD. As an example, the insulating layer INS may be formed at a height that is lower than or equal to a value corresponding to a thickness difference between a first portion LEP1 and a third portion LEP3 of the light-emitting element LE and/or a thickness difference between a second portion LEP2 and the third portion LEP3 of the light-emitting element LE. However, embodiments are not limited thereto. For example, in consideration of a structure of the light-emitting element LE, a method for arranging the light-emitting element LE on the first pad electrode APD and the second pad electrode CPD or bonding the light-emitting element LE to the first pad electrode APD and the second pad electrode CPD, or the like, a size or a position of the insulating layer INS may be appropriately adjusted or optimized so that the insulating layer INS does not interfere with a stable disposition of the light-emitting element LE. In addition, the size or the position of the insulating layer INS may be appropriately adjusted or optimized so as to appropriately reduce or prevent a short-circuit defect between the first pad electrode APD and the second pad electrode CPD.

The organic layer INS1 may be located on the third planarization layer VIA3. In one or more embodiments, the organic layer INS1 may cover one end of each of the first pad electrode APD and the second pad electrode CPD. For example, the organic layer INS1 may cover one end of the first pad electrode APD facing the second pad electrode CPD, and may cover one end of the second pad electrode CPD facing the first pad electrode APD.

The organic layer INS1 may include an organic insulating material. In one or more embodiments, the organic layer INS1 and the fourth planarization layer VIA4 may include the same organic insulating material. For example, the organic layer INS1 and the fourth planarization layer VIA4 may be formed concurrently or substantially simultaneously using the organic insulating material described above as the material of the fourth planarization layer VIA4 or another organic insulating material.

The fourth planarization layer VIA4 and the organic layer INS1 may be formed integrally with each other, or may be separated from each other. For example, in plan view, the fourth planarization layer VIA4 and the organic layer INS1 may be connected to each other or separated from each other in another area (e.g., an outer area of a light-emitting element disposition area). In describing embodiments, the fourth planarization layer VIA4 and the organic layer INS1 have been described as different components, but embodiments are not limited thereto. For example, the organic layer INS1 may also be considered as a portion of the fourth planarization layer VIA4.

A height (or a thickness) of the organic layer INS1 may be lower than a height (or a thickness) of the fourth planarization layer VIA4. For example, the organic layer INS1 and the fourth planarization layer VIA4 may be formed at different heights using a halftone mask. The height of the insulating layer INS may be appropriately adjusted by adjusting the height of the organic layer INS1. For example, the organic layer INS1 may be formed at a height corresponding to a reference value set in consideration of the stable disposition of the light-emitting element LE, electrical stability of the first pad electrode APD and the second pad electrode CPD (e.g., insulation between the first pad electrode APD and the second pad electrode CPD), and the like. In one or more embodiments, the organic layer INS1 may have a thickness of about 1.5 μm or more, and a total thickness of the insulating layer INS including the organic layer INS1 and the inorganic layer INS2 may be about 2 μm or more. Accordingly, the electrical stability of the first pad electrode APD and the second pad electrode CPD may be improved. The fourth planarization layer VIA4 may have a thickness of about 2 μm or more, but embodiments are not limited thereto.

One or more embodiments in which the organic layer INS1 has a step caused by the first pad electrode APD and the second pad electrode CPD has been illustrated in FIGS. 7 and 8, but embodiments are not limited thereto. For example, an upper surface of the organic layer INS1 may be substantially flat.

The inorganic layer INS2 may be located on the organic layer INS1. For example, the inorganic layer INS2 may be directly located on the organic layer INS1. The inorganic layer INS2 may stably or entirely cover the organic layer INS1. For example, the inorganic layer INS2 may completely cover the organic layer INS1. As an example, the inorganic layer INS2 may completely cover the upper surface and side surfaces of the organic layer INS1. Accordingly, it is possible to reduce or prevent an outgassing problem that may occur in a fabricating process or the like of the display panel 100.

The inorganic layer INS2 may include an inorganic insulating material. In one or more embodiments, the first passivation layer PVX1 and the inorganic layer INS2 may include the same inorganic insulating material. For example, the first passivation layer PVX1 and the inorganic layer INS2 may be formed concurrently or substantially simultaneously using the inorganic insulating material described above as the material of the first passivation layer PVX1 or another inorganic insulating material. In one or more embodiments, the first passivation layer PVX1 and the inorganic layer INS2 may be formed at the same thickness. Accordingly, a process of forming the first passivation layer PVX1 and the inorganic layer INS2 may be simplified.

The first passivation layer PVX1 and the inorganic layer INS2 may be formed integrally with each other or separated from each other. For example, in plan view, the first passivation layer PVX1 and the inorganic layer INS2 may be connected to each other or separated from each other in another area (e.g., an outer area of a light-emitting element disposition area). In describing embodiments, the first passivation layer PVX1 and the inorganic layer INS2 have been described as different components, but embodiments are not limited thereto. For example, the inorganic layer INS2 may also be considered as a portion of the first passivation layer PVX1.

According to embodiments, by arranging the insulating layer INS including the organic layer INS1 between the first pad electrode APD and the second pad electrode CPD, it is possible to appropriately protect the first pad electrode APD and the second pad electrode CPD (or the transparent electrodes TPD on the first pad electrode APD and the second pad electrode CPD) during the fabrication of the display panel 100, and to reduce or prevent the likelihood of the first pad electrode APD and the second pad electrode CPD being connected to each other. For example, it is possible to prevent or reduce damage, such as scratches from occurring in the first pad electrode APD and the second pad electrode CPD (or the transparent electrodes TPD on the first pad electrode APD and the second pad electrode CPD) by the insulating layer INS. In addition, even though damage, such as a scratch, occurs in at least one of the first pad electrode APD or the second pad electrode CPD (or at least one of the transparent electrodes TPD), the insulation between the first pad electrode APD and the second pad electrode CPD may be stably secured by the insulating layer INS. Accordingly, the likelihood of a short-circuit defect between the first pad electrode APD and the second pad electrode CPD may be reduced or prevented, and the electrical stability of the first pad electrode APD and the second pad electrode CPD may be secured. Accordingly, it is possible to reduce or prevent the likelihood of a defect of the display device 10 and to improve a yield of the display device 10.

In some embodiments, when the organic layer INS1 covers one end of each of the first pad electrode APD and the second pad electrode CPD, the likelihood of a short-circuit defect between the first pad electrode APD and the second pad electrode CPD may be more effectively reduced or prevented. In addition, in some embodiments, when the first passivation layer PVX1 stably or completely covers the fourth planarization layer VIA4 and the inorganic layer INS2 stably or completely covers the organic layer INS1, a gas that may be emitted from the fourth planarization layer VIA4, the organic layer INS1, and the like, in the fabricating process, or the like, of the display panel 100 may be appropriately blocked. Accordingly, the likelihood of a problem (e.g., contamination, etc.) due to outgassing may be reduced or prevented.

A light-emitting element layer including the light-emitting elements LE may be located on the first pad electrode APD and the second pad electrode CPD. In one or more embodiments, the light-emitting element LE may be a flip chip-type micro LED. For example, the light-emitting element LE may be a flip chip-type micro LED including a first electrode AE and a second electrode CE located to face the first pad electrode APD and the second pad electrode CPD. The light-emitting element LE may be electrically connected between the first pad electrode APD and the second pad electrode CPD.

In embodiments, the insulating layer INS is located between the first pad electrode APD and the second pad electrode CPD, and thus, the light-emitting element LE may be located on the first pad electrode APD, the second pad electrode CPD, and the insulating layer INS. The light-emitting element LE may include a first portion LEP1 located above the first pad electrode APD, a second portion LEP2 located above the second pad electrode CPD, and a third portion LEP3 located above the insulating layer INS.

The first portion LEP1 and the second portion LEP2 may include the first electrode AE and the second electrode CE of the light-emitting element LE, respectively. The third portion LEP3 may connect the first portion LEP1 and the second portion LEP2 to each other. In one or more embodiments, a thickness of the third portion LEP3 may be less than a thickness of each of the first portion LEP1 and the second portion LEP2. Accordingly, even though the insulating layer INS is located below the third portion LEP3, the light-emitting element LE may be stably located or bonded between the first pad electrode APD and the second pad electrode CPD.

The light-emitting element LE may be an inorganic light-emitting element made of an inorganic material, such as GaN. Each of lengths of the light-emitting element LE in the first direction DR1, the second direction DR2, and the third direction DR3 may be several micrometers (μm) to several hundreds of micrometers (μm). For example, each of lengths of the light-emitting element LE in the first direction DR1, the second direction DR2, and the third direction DR3 may be approximately 100 μm or less.

The light-emitting elements LE may be grown and formed on a semiconductor substrate, such as a silicon wafer. Each of the light-emitting elements LE may be directly transferred from the silicon wafer onto the first pad electrode APD and the second pad electrode CPD of the substrate SUB. Alternatively, each of the light-emitting elements LE may be transferred onto the first pad electrode APD and the second pad electrode CPD of the substrate SUB through an electrostatic method using an electrostatic head, or a stamp method using an elastic polymer material, such as polydimethylsiloxane (PDMS) or silicon, as a material of a transfer substrate.

Each of the light-emitting elements LE may include a base substrate SSUB, an n-type semiconductor layer NSEM, an active layer MQW, a p-type semiconductor layer PSEM, the first electrode AE, and the second electrode CE.

The base substrate SSUB may be a semiconductor substrate including a semiconductor material. As an example, the base substrate SSUB may be a sapphire substrate.

The n-type semiconductor layer NSEM may be located on one surface of the base substrate SSUB. For example, the n-type semiconductor layer NSEM may be located on a lower surface of the base substrate SSUB. The n-type semiconductor layer NSEM may include a semiconductor material doped with an n-type dopant, such as Si, Ge, or Sn. As an example, the n-type semiconductor layer NSEM may be made of GaN including an n-type dopant.

The active layer MQW may be located on a portion of one surface of the n-type semiconductor layer NSEM. The active layer MQW may include a material having a single or multiple quantum well structure. When the active layer MQW includes the material having the multiple quantum well structure, the active layer MQW may have a structure in which a plurality of well layers and barrier layers are alternately stacked. In one or more embodiments, the well layer may be made of InGaN, and the barrier layer may be made of GaN or AlGaN, but the present disclosure is not limited thereto. Alternatively, the active layer MQW may have a structure in which semiconductor materials having great band gap energy and semiconductor materials having small band gap energy are alternately stacked, and may include other Group Ill to Group V semiconductor materials depending on a wavelength band of emitted light.

The p-type semiconductor layer PSEM may be located on one surface of the active layer MQW. The p-type semiconductor layer PSEM may include a semiconductor material doped with a p-type dopant, such as Mg, Zn, Ca, Se, or Ba. As an example, the p-type semiconductor layer PSEM may be made of GaN including a p-type dopant.

The first electrode AE may be located on the p-type semiconductor layer PSEM, and the second electrode CE may be located on another portion of one surface of the n-type semiconductor layer NSEM. Another portion of one surface of the n-type semiconductor layer NSEM on which the second electrode CE is located may be spaced apart from a portion of one surface of the n-type semiconductor layer NSEM on which the active layer MQW is located. As an example, the first electrode AE may be an anode electrode of the light-emitting element LE, and the second electrode CE may be a cathode electrode of the light-emitting element LE.

The first electrode AE and the transparent electrode TPD on the first pad electrode APD (or the first pad electrode APD) may be adhered to each other through a conductive adhesive member, such as an anisotropic conductive film (ACF) or an anisotropic conductive paste (ACP) or may be adhered to each other through a soldering process.

The first pad PD1 may include the first to fifth sub-pads SPD1, SPD2, SPD3, SPD4, and SPD5. The second sub-pad SPD2 may be located on the first sub-pad SPD1. The third sub-pad SPD3 may be located on the second sub-pad SPD2. The fourth sub-pad SPD4 may be located on the third sub-pad SPD3. The fifth sub-pad SPD5 may be located on the fourth sub-pad SPD4.

The back-side line layer BLIL may include the back-side lines (or rear lines) BFL including the first back-side lines BFL1 and the back surface pads including the second pads PD2 and the third pads PD3.

The back-side line layer BLIL includes at least one conductive layer and at least one insulating layer. For example, the back-side line layer BLIL may include a second passivation layer PVX2, a back surface conductive layer BCL, a second transparent conductive layer TCL2, a fifth planarization layer VIA5, and a third passivation layer PVX3 that are sequentially located on the second surface BS of the substrate SUB.

The second passivation layer PVX2 may be located on the second surface BS of the substrate SUB. The second passivation layer PVX2 may include an inorganic insulating material. For example, the second passivation layer PVX2 may be formed as an inorganic layer, such as a silicon nitride layer, a silicon oxynitride layer, a silicon oxide layer, a titanium oxide layer, or an aluminum oxide layer. The second passivation layer PVX2 may also be omitted.

The back surface conductive layer BCL may be located on one surface of the second passivation layer PVX2. The back surface conductive layer BCL may include the first back-side lines BFL1. The back surface conductive layer BCL may include a conductive material. For example, the back surface conductive layer BCL may be formed as a single layer or multiple layers made of any one of molybdenum (Mo), aluminum (Al), chromium (Cr), gold (Au), titanium (Ti), nickel (Ni), neodymium (Nd), or copper (Cu), or alloys thereof.

In one or more embodiments, portions of each of the first back-side lines BFL1 may form the second pad PD2 and the third pad PD3. For example, one end of each of the first back-side lines BFL1 may form a first pad layer PD21 of the second pad PD2, and the other end of each of the first back-side lines BFL1 may form a first pad layer PD31 of the third pad PD3.

The back surface conductive layer BCL may further include the second back-side lines BFL2 illustrated in FIG. 2. For example, the first back-side lines BFL1 and the second back-side lines BFL2 may be formed concurrently or substantially simultaneously using the same conductive material.

The second transparent conductive layer TCL2 may be located on a portion of the back surface conductive layer BCL. The second transparent conductive layer TCL2 may include a second pad layer PD22 of the second pad PD2, and a second pad layer PD32 of the third pad PD3. The second pad layer PD22 of the second pad PD2 and the second pad layer PD32 of the third pad PD3 may be located on respective surfaces of the first pad layer PD21 of the second pad PD2 and the first pad layer PD31 of the third pad PD3. For example, the second pad PD2 may be formed as multiple layers including the first pad layer PD21 and the second pad layer PD22, and the third pad PD3 may be formed as multiple layers including the first pad layer PD31 and the second pad layer PD32. The second transparent conductive layer TCL2 may include a conductive material. For example, the second transparent conductive layer TCL2 may be made of a transparent conductive oxide, such as ITO or IZO.

The fifth planarization layer VIA5 may be located on one surfaces of the back surface conductive layer BCL and the second transparent conductive layer TCL2. The fifth planarization layer VIA5 may include an organic insulating material. For example, the fifth planarization layer VIA5 may be formed as an organic layer made of an acrylic resin, an epoxy resin, a phenolic resin, a polyamide resin, a polyimide resin, or the like. The fifth planarization layer VIA5 may cover portions (e.g., edges of one or more respective sides) of the second pad PD2 and the third pad PD3, and expose other portions of the second pad PD2 and the third pad PD3.

The third passivation layer PVX3 may be located on one surface of the fifth planarization layer VIA5. The third passivation layer PVX3 may include an inorganic insulating material. For example, the third passivation layer PVX3 may be formed as an inorganic layer, such as a silicon nitride layer, a silicon oxynitride layer, a silicon oxide layer, a titanium oxide layer, or an aluminum oxide layer.

The first side line SIL1 may be located on the first surface FS, the first chamfered surface CS1, the first side surface SS1, the second chamfered surface CS2, and the second surface BS of the substrate SUB. The first side line SIL1 may be located on the first pad PD1 and the second pad PD2, and may be connected to the first pad PD1 and the second pad PD2.

The overcoat layer OC may be located on the first surface FS, the first chamfered surface CS1, the first side surface SS1, the second chamfered surface CS2, and the second surface BS of the substrate SUB. The overcoat layer OC may cover the side line SIL. The overcoat layer OC may include an organic insulating material. For example, the overcoat layer OC may be formed as an organic layer made of an acrylic resin, an epoxy resin, a phenolic resin, a polyamide resin, a polyimide resin, or the like.

The first circuit board 200 may be located on the second surface BS of the substrate SUB. As an example, the first circuit board 200 may be located on one surface of the back-side line layer BLIL.

The first circuit board 200 may be connected to the third pad PD3 through a conductive adhesive member CAM. The conductive adhesive member CAM may be an anisotropic conductive film or an anisotropic conductive paste.

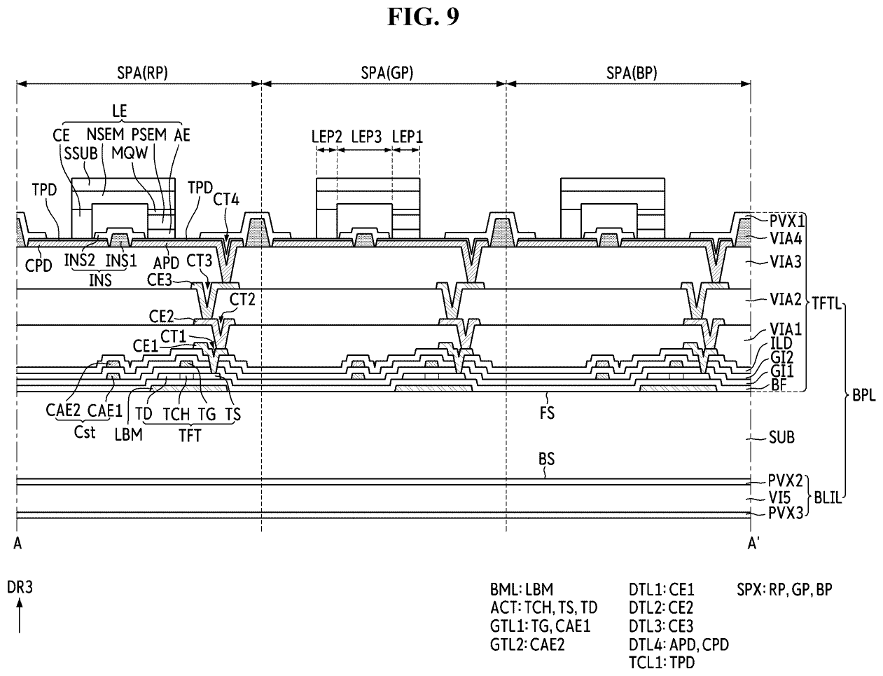

FIG. 9 is a cross-sectional view illustrating a display panel according to one or more embodiments. For example, FIG. 9 illustrates one or more embodiments of a cross section of a portion of the display panel 100 taken along the line A-A′ of FIG. 3.

FIG. 9 illustrates one or more embodiments different from one or more embodiments of FIGS. 7 and 8 in relation to the insulating layer INS and the fourth planarization layer VIA4. In describing one or more embodiments of FIG. 9, an overlapping description of a components that are substantially the same as or similar to one or more embodiments of FIGS. 7 and 8 is omitted.

Referring to FIG. 9, the organic layer INS1 of the insulating layer INS may not overlap the first pad electrode APD and the second pad electrode CPD. A height of the organic layer INS1 may be higher than a height of the first pad electrode APD and the second pad electrode CPD, or higher than a height of the transparent electrodes TPD on the first pad electrode APD and the second pad electrode CPD. For example, a height of the insulating layer INS including the organic layer INS1 may be higher than the height of the transparent electrodes TPD on the first pad electrode APD and the second pad electrode CPD. Accordingly, even though the organic layer INS1 does not overlap the first pad electrode APD and the second pad electrode CPD, it is possible to appropriately protect the first pad electrode APD and the second pad electrode CPD, and to reduce or prevent the likelihood of a short-circuit defect between the first pad electrode APD and the second pad electrode CPD.

In one or more embodiments, the fourth planarization layer VIA4 may not overlap the first pad electrode APD and the second pad electrode CPD. Accordingly, an area where the light-emitting element LE may be located or connected may be expanded.

One or more embodiments in which the insulating layer INS and the fourth planarization layer VIA4 overlap the first pad electrode APD and the second pad electrode CPD (e.g., portions thereof) has been disclosed in FIGS. 7 and 8, and one or more embodiments in which the insulating layer INS and the fourth planarization layer VIA4 do not overlap the first pad electrode APD and the second pad electrode CPD has been disclosed in FIG. 9, but embodiments are not limited thereto. For example, one of the insulating layer INS or the fourth planarization layer VIA4 may overlap the first pad electrode APD and the second pad electrode CPD, and the other of the insulating layer INS and the fourth planarization layer VIA4 might not overlap the first pad electrode APD and the second pad electrode CPD. As an example, all possible combinations of embodiments may fall within the scope of the present disclosure.

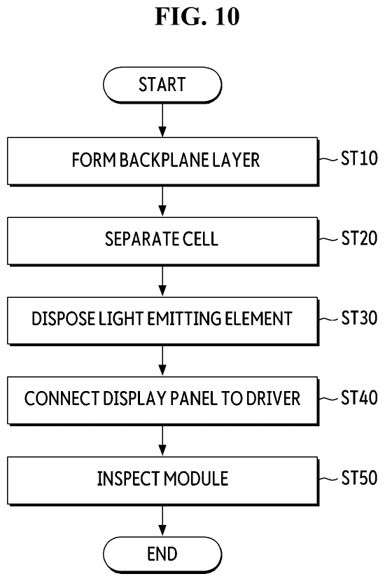

FIG. 10 is a flowchart illustrating a method for fabricating the display device according to one or more embodiments.

Referring to FIG. 10 in addition to FIGS. 1 to 9, the backplane layer BPL of the display panel 100 is first formed. For example, a mother substrate including a plurality of cell regions for fabricating a plurality of display panels 100 may be prepared, and the thin film transistor layer TFTL and the back-side line layer BLIL may be formed on a front surface and a back surface of the mother substrate, respectively (ST10).

Next, the plurality of cell regions may be separated. For example, by cutting the mother substrate according to each cell region, the cell regions of the mother substrate on which the backplane layer BPL is formed may be separated as individual backplane substrates (ST20).

Next, each display panel 100 may be fabricated by performing subsequent panel processes including a process of arranging light-emitting elements. For example, the side lines SIL and the overcoat layer OC may be formed on each backplane substrate. In addition, the light-emitting element LE may be located in each sub-pixel area SPA. As an example, the light-emitting element LE may be bonded onto the transparent electrodes TPD on the first pad electrode APD and the second pad electrode CPD (or the first pad electrode APD and the second pad electrode CPD) of the sub-pixel area SPA by performing a bonding process using a conductive adhesive, a soldering process, or the like (ST30).

Next, the display panel 100 may be connected to a driver. For example, by arranging the first circuit boards 200 and the second circuit board 400 on a back surface of the display panel 100, or by bonding the first circuit boards 200 and the second circuit board 400 onto the back surface of the display panel 100 using the conductive adhesive CAM, the source drivers 300 and the power supply 500 may be electrically connected to the display panel 100 (ST40).

Next, a module inspection may be performed. For example, by performing a module inspection including a lighting inspection, it is possible to determine whether or not the display device 10 including the display panel 100 and the driver (e.g., the source drivers 300 and the power supply 500) is a good product (ST50).

Accordingly, a substantial fabricating process of the display device 10 may be completed. In one or more embodiments, a module assembly process or the like may be additionally performed after the fabrication of the display device 10.

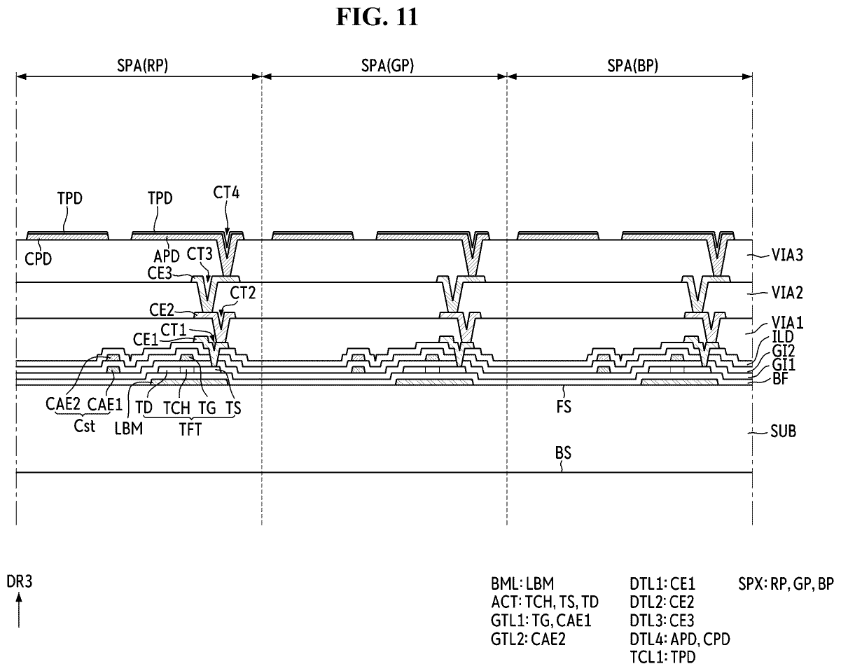

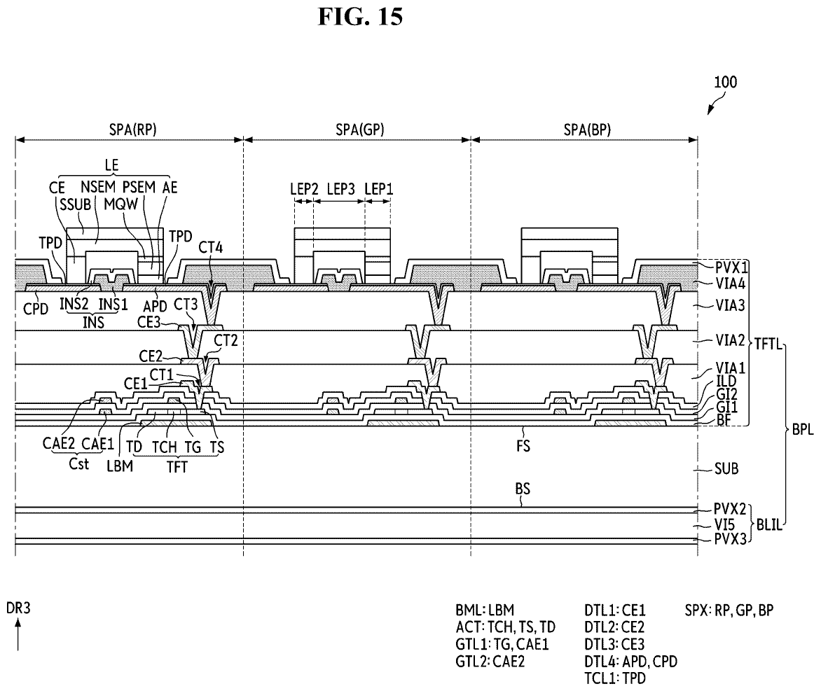

FIGS. 11 to 15 are cross-sectional views illustrating a method for fabricating the display device according to one or more embodiments. For example, FIGS. 11 to 14 sequentially illustrate a backplane-layer-forming operation (ST10) of FIG. 10, and FIG. 15 illustrates a cross section of the display panel 100 fabricated through a cell-separating operation (ST20) and a light-emitting-element-arranging operation (ST30) of FIG. 10. FIGS. 11 to 15 illustrate cross sections corresponding to a portion of the display panel 100 illustrated in FIG. 7.

Referring to FIG. 11, a plurality of conductive layers and insulating layers including the thin film transistor TFT, the first pad electrode APD, and the second pad electrode CPD may be formed on/above the first surface FS of the substrate SUB. For example, the bottom metal layer BML, the buffer layer BF, the active layer ACT, the first gate-insulating layer GI1, the first gate layer GTL1, the second gate-insulating layer GI2, the second gate layer GTL2, the interlayer insulating layer ILD, the first data metal layer DTL1, the first planarization layer VIA1, the second data metal layer DTL2, the second planarization layer VIA2, the third data metal layer DTL3, the third planarization layer VIA3, the fourth data metal layer DTL4, and the first transparent conductive layer TCL1 may be sequentially formed on the first surface FS of the substrate SUB.

Patterns of the bottom metal layer BML, the first gate layer GTL1, the second gate layer GTL2, the first data metal layer DTL1, the second data metal layer DTL2, the third data metal layer DTL3, the fourth data metal layer DTL4, and the first transparent conductive layer TCL1 may be formed by processes of forming conductive films using the respective conductive materials, and by processes of patterning the conductive films. For example, patterns of respective conductive layers may be formed by applying the respective conductive materials onto the first surface FS of the substrate SUB to form single-layer or multilayer conductive films, and by patterning the conductive films by etching processes using a mask. As an example, after a first conductive film for forming the fourth data metal layer DTL4 and a second conductive film for forming the first transparent conductive layer TCL1 are sequentially formed, the first conductive film and the second conductive film may be etched. Accordingly, the first pad electrode APD, the second pad electrode CPD, and the transparent electrodes TPD may be formed in each sub-pixel area SPA.

The active layer ACT may be formed by a process of forming a semiconductor film using a semiconductor material and a process of patterning the semiconductor film. In one or more embodiments, a doping process for making portions (e.g., the first electrode TS and the second electrode TD) of the active layer ACT conductive may be additionally performed.

The buffer layer BF, the first gate-insulating layer GI1, the second gate-insulating layer GI2, the interlayer insulating layer ILD, the first planarization layer VIA1, the second planarization layer VIA2, and the third planarization layer VIA3 may be formed by processes of forming insulating films (single-layer or multi-layer insulating films) using respective insulating materials. In one or more embodiments, a contact hole may be formed in at least one of the first gate-insulating layer GI1, the second gate-insulating layer GI2, the interlayer insulating layer ILD, the first planarization layer VIA1, the second planarization layer VIA2, or the third planarization layer VIA3 by an etching process utilizing a mask.

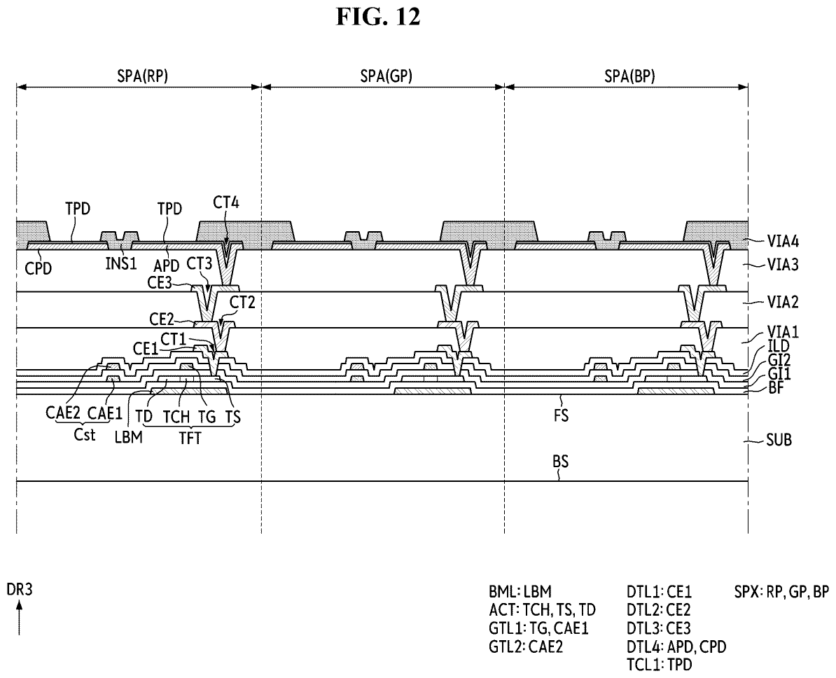

Referring to FIG. 12, the fourth planarization layer VIA4 and the organic layer INS1 may be formed on the third planarization layer VIA3, the fourth data metal layer DTL4, and the first transparent conductive layer TCL1.

The fourth planarization layer VIA4 and the organic layer INS1 may be formed by a process of forming an insulating film using an organic insulating material and a process of patterning the insulating film. For example, after an insulating film is formed on the third planarization layer VIA3, the fourth data metal layer DTL4, and the first transparent conductive layer TCL1 by applying the organic insulating material described above as the material of the fourth planarization layer VIA4 and the organic layer INS1 or another organic insulating material, the fourth planarization layer VIA4 and the organic layer INS1 may be formed by etching the insulating film.

In one or more embodiments, the fourth planarization layer VIA4 and the organic layer INS1 may be formed concurrently or substantially simultaneously at different heights by a single mask process using a halftone mask. For example, by forming a photoresist pattern having different thicknesses on the insulating film according to positions where the fourth planarization layer VIA4 and the organic layer INS1 are to be formed using a halftone mask, the fourth planarization layer VIA4 and the organic layer INS1 may be formed at different heights in a subsequent etching process of the insulating film. As an example, the organic layer INS1 may be formed at a lower height than the fourth planarization layer VIA4. However, embodiments are not limited thereto, and the fourth planarization layer VIA4 and the organic layer INS1 may be formed at different heights using different process methods.

The organic layer INS1 may be formed at least between the first pad electrode APD and the second pad electrode CPD. In one or more embodiments, the organic layer INS1 may cover one ends of the first pad electrode APD and the second pad electrode CPD, but is not limited thereto.

The fourth planarization layer VIA4 may be formed at an edge of each sub-pixel area SPA. In one or more embodiments, the fourth planarization layer VIA4 may cover the other ends of the first pad electrode APD and the second pad electrode CPD, but is not limited thereto.

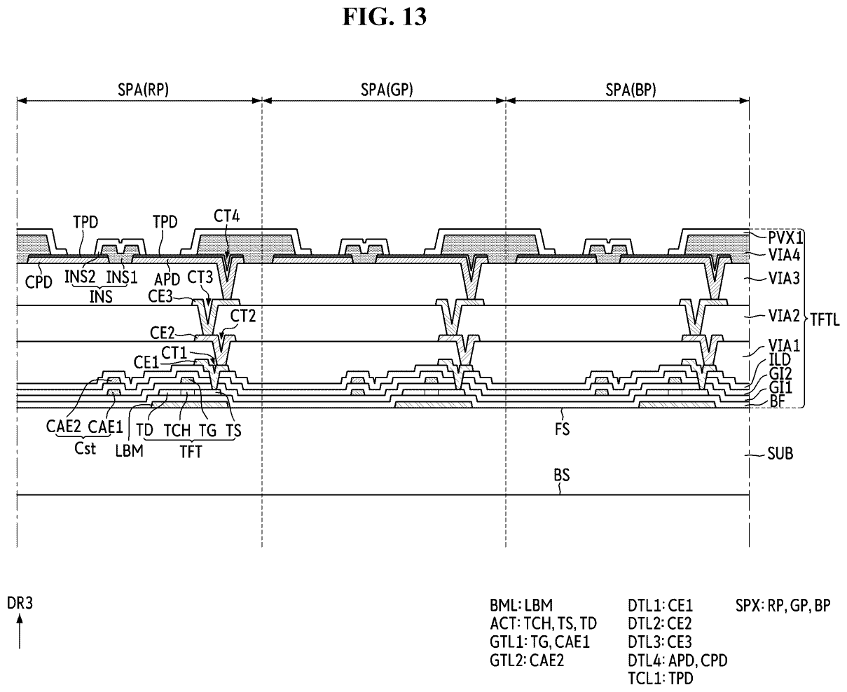

Referring to FIG. 13, the first passivation layer PVX1 and the inorganic layer INS2 may be formed on the fourth planarization layer VIA4 and the organic layer INS1, respectively. The first passivation layer PVX1 and the inorganic layer INS2 may be formed by a process of forming an insulating film using an inorganic insulating material and a process of patterning the insulating film. The first passivation layer PVX1 and the inorganic layer INS2 may be formed concurrently or substantially simultaneously using the same inorganic insulating material. In one or more embodiments, the first passivation layer PVX1 may completely cover the fourth planarization layer VIA4, and the inorganic layer INS2 may completely cover the organic layer INS1. Accordingly, it is possible to prevent or improve an outgassing problem that may occur in a fabricating process or the like of the display panel 100.

By fabrication operations illustrated in FIGS. 12 and 13, the insulating layer INS covering one ends of the first pad electrode APD and the second pad electrode CPD may be formed between the first pad electrode APD and the second pad electrode CPD. In addition, by fabrication operations illustrated in FIGS. 11 to 13, the thin film transistor layer TFTL may be formed on the first surface FS of the substrate SUB.

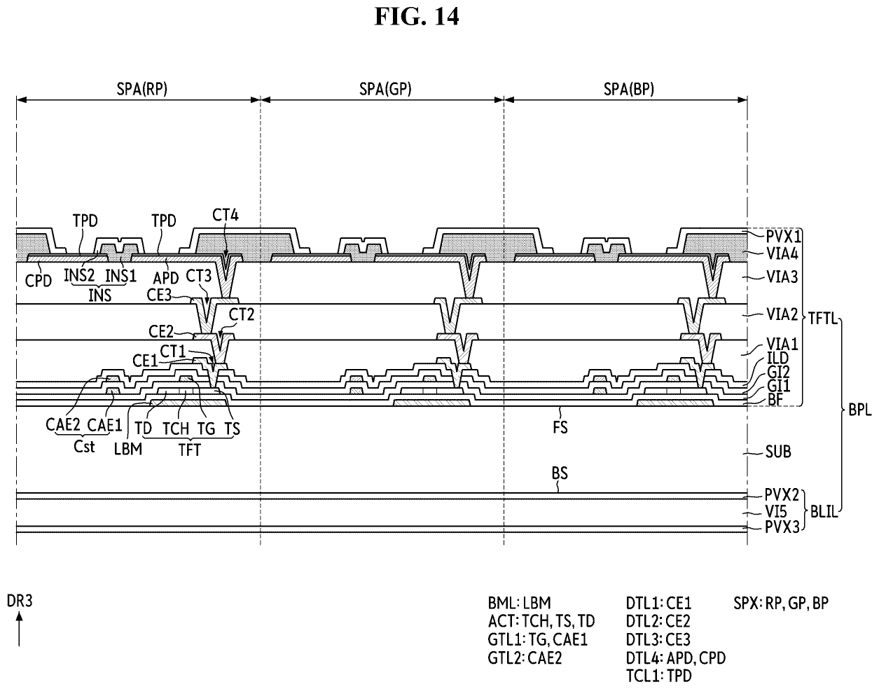

Referring to FIG. 14, the back-side line layer BLIL may be formed on the second surface BS of the substrate SUB. For example, the second passivation layer PVX2, the back surface conductive layer BCL, and the second transparent conductive layer TCL2 illustrated in FIG. 8, and the fifth planarization layer VIA5, and the third passivation layer PVX3 may be sequentially formed on the second surface BS of the substrate SUB.

In embodiments, a process for forming the back-side line layer BLIL may be performed in a state in which portions of the first pad electrode APD and the second pad electrode CPD or portions of the transparent electrodes TPD are exposed. In a process performed in a state in which portions of the first pad electrode APD and the second pad electrode CPD or the transparent electrodes TPD are exposed prior to mounting of the light-emitting element LE, such as the process for forming the back-side line layer BLIL, or a process for forming the side lines SIL performed after the process for forming the back-side line layer BLIL, there is a possibility that damage, such as a scratch, will occur in at least one of the first pad electrode APD, the second pad electrode CPD, or the transparent electrodes TPD. However, according to embodiments, the insulating layer INS including the organic layer INS1 is located between the first pad electrode APD and the second pad electrode CPD, and thus, insulation between the first pad electrode APD and the second pad electrode CPD may be improved or secured. For example, the possibility that the damage will occur in the first pad electrode APD, the second pad electrode CPD, and the transparent electrodes TPD may be reduced by the insulating layer INS, and even though the damage, such as the scratch, occurs in at least one of the first pad electrode APD, the second pad electrode CPD, or the transparent electrodes TPD, the insulation between the first pad electrode APD and the second pad electrode CPD may be secured by the insulating layer INS. Accordingly, it is possible to prevent or reduce a defect that may occur in the fabricating process of the display device 10, and to improve a yield of the display device 10.

By fabrication operations illustrated in FIGS. 11 to 14, the backplane layer BPL of the display panel 100 may be formed.

Referring to FIG. 15, the light-emitting elements LE may be located on the backplane layer BPL. For example, the light-emitting element LE may be bonded onto the first pad electrode APD and the second pad electrode CPD located in each sub-pixel area SPA. For example, the transparent electrodes TPD, which are on the first pad electrode APD and the second pad electrode CPD, and the light-emitting element LE may be adhered to each other by a bonding process using a conductive adhesive member or a soldering process. The light-emitting element LE may be located on the first pad electrode APD, the second pad electrode CPD, the transparent electrodes TPD, and the insulating layer INS, and may be electrically connected between the first pad electrode APD and the second pad electrode CPD.

Meanwhile, in one or more embodiments, the cell-separating operation (ST20) of FIG. 10, a side-line-forming operation, or the like, may be additionally performed after the formation of the backplane layer BPL.

By the above-described processes, the display panel 100 of the display device 10 may be fabricated.

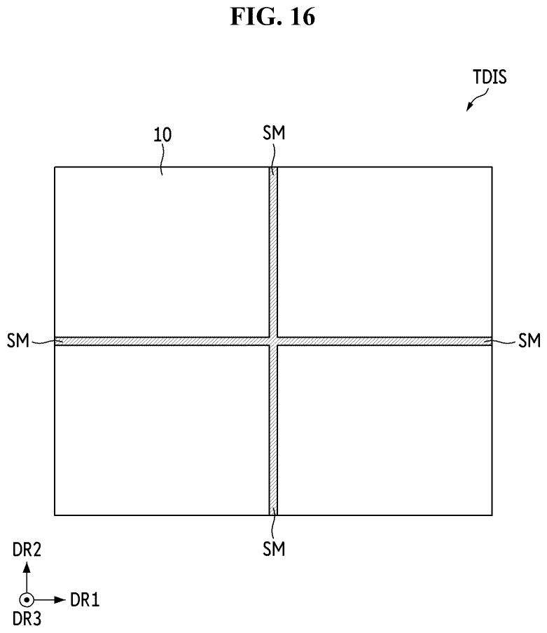

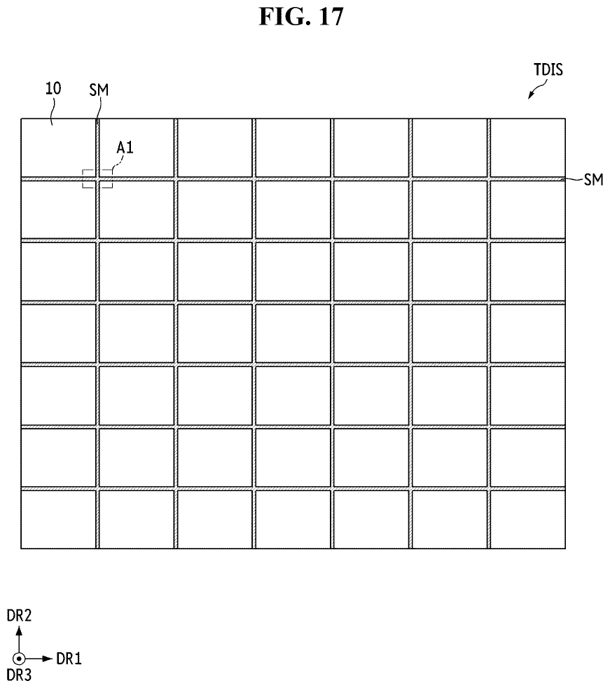

FIG. 16 is a plan view illustrating a tiled display device according to one or more embodiments. FIG. 17 is a plan view illustrating a tiled display device according to one or more embodiments. For example, FIGS. 16 and 17 illustrate different embodiments in relation to the number and/or an arrangement structure of display devices 10 constituting a tiled display device TDIS.

Referring to FIGS. 16 and 17, a tiled display device TDIS may include a plurality of display devices 10, and a seam portion SM located between the display devices 10. The display devices 10 may be arranged along the first direction DR1 and/or the second direction DR2.

In one or more embodiments, the tiled display device TDIS may include four display devices 10 arranged in a matrix form of two rows and two columns along the first direction DR1 and the second direction DR2, as illustrated in FIG. 16.

The number, an arrangement structure, and the like, of display devices 10 constituting the tiled display device TDIS may be changed depending on embodiments. For example, a larger tiled display device TDIS may be implemented by using a larger number of display devices 10. As an example, by arranging display devices 10 each having a size of about 12.7 inches in a matrix form of seven rows and seven columns, as illustrated in FIG. 17, a larger tiled display device TDIS having a size of approximately 89 inches may be implemented. Depending on a size, a shape, an arrangement structure, and the like, of each of the display devices 10 constituting the tiled display device TDIS, a tiled display device TDIS having various shapes and/or sizes may be implemented.

In one or more embodiments, at least one of the display devices 10 may be the display device 10 according to at least one of embodiments of FIGS. 1 to 9. For example, at least one of the display devices 10 may include the insulating layer INS located between the first pad electrode APD and the second pad electrode CPD of each sub-pixel area SPA, and including the organic layer INS1 and the inorganic layer INS2. In one or more embodiments, the display devices 10 may have substantially the same shape, size, and structure. The display devices 10 may be located in the same direction or different directions.

In one or more embodiments, each of the display devices 10 may have a rectangular shape in plan view, but is not limited thereto. Some or all of the display devices 10 may be located at edges of the tiled display device TDIS, and may form one side of the tiled display device TDIS.

The seam portion SM may be located between the display devices 10. For example, the seam portion SM may be located between the display devices 10 neighboring to each other in the first direction DR1 and between the display devices 10 neighboring to each other in the second direction DR2.

In one or more embodiments, the seam portion SM may include a coupling member or an adhesive member. In this case, the display devices 10 may be connected to each other through the coupling member or the adhesive member of the seam portion SM.

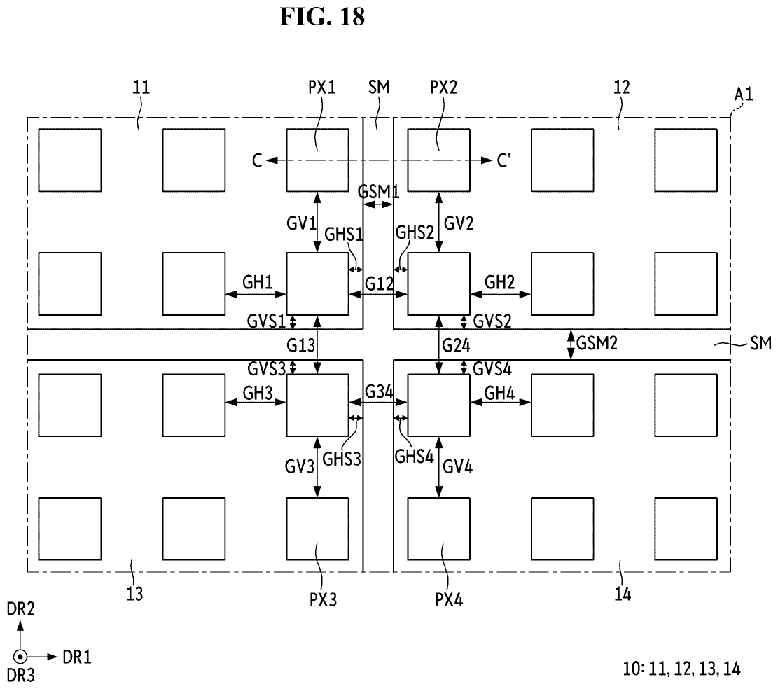

FIG. 18 is a plan view illustrating a seam portion of the tiled display device according to one or more embodiments in detail. For example, FIG. 18 is an enlarged view illustrating area A1 of FIG. 17 in detail.

Referring to FIG. 18, the seam portion SM may have a cross shape or a plus sign (+) shape in plan view in an area where a first display device 11, a second display device 12, a third display device 13, and a fourth display device 14 are adjacent to each other. The seam portion SM may be located between the first display device 11 and the second display device 12, between the first display device 11 and the third display device 13, between the second display device 12 and the fourth display device 14, and between the third display device 13 and the fourth display device 14.

The first display device 11 may include first pixels PX1 arranged in a matrix form in the first direction DR1 and the second direction DR2. The second display device 12 may include second pixels PX2 arranged in a matrix form in the first direction DR1 and the second direction DR2. The third display device 13 may include third pixels PX3 arranged in a matrix form in the first direction DR1 and the second direction DR2. The fourth display device 14 may include fourth pixels PX4 arranged in a matrix form in the first direction DR1 and the second direction DR2.

A minimum distance between the first pixels PX1 neighboring to each other in the first direction DR1 may be defined as a first horizontal spaced distance GH1, and a minimum distance between the second pixels PX2 neighboring to each other in the first direction DR1 may be defined as a second horizontal spaced distance GH2. The first horizontal spaced distance GH1 and the second horizontal spaced distance GH2 may be substantially the same as each other.

The seam portion SM may be located between the first pixel PX1 and the second pixel PX2 neighboring to each other in the first direction DR1. A minimum distance G12 between the first pixel PX1 and the second pixel PX2 neighboring to each other in the first direction DR1 may be the sum of a minimum distance GHS1 between the first pixel PX1 and the seam portion SM in the first direction DR1, a minimum distance GHS2 between the second pixel PX2 and the seam portion SM in the first direction DR1, and a width GSM1 of the seam portion SM in the first direction DR1.

In one or more embodiments, the minimum distance G12 between the first pixel PX1 and the second pixel PX2 neighboring to each other in the first direction DR1, the first horizontal spaced distance GH1, and the second horizontal spaced distance GH2 may be substantially the same as or similar to each other. As an example, the minimum distance GHS1 between the first pixel PX1 and the seam portion SM in the first direction DR1 may be less than the first horizontal spaced distance GH1, and the minimum distance GHS2 between the second pixel PX2 and the seam portion SM in the first direction DR1 may be less than the second horizontal spaced distance GH2. In addition, the width GSM1 of the seam portion SM in the first direction DR1 may be less than the first horizontal spaced distance GH1 or the second horizontal spaced distance GH2.

A minimum distance between the third pixels PX3 neighboring to each other in the first direction DR1 may be defined as a third horizontal spaced distance GH3, and a minimum distance between the fourth pixels PX4 neighboring to each other in the first direction DR1 may be defined as a fourth horizontal spaced distance GH4. The third horizontal spaced distance GH3 and the fourth horizontal spaced distance GH4 may be substantially the same as each other.

The seam portion SM may be located between the third pixel PX3 and the fourth pixel PX4 neighboring to each other in the first direction DR1. A minimum distance G34 between the third pixel PX3 and the fourth pixel PX4 neighboring to each other in the first direction DR1 may be the sum of a minimum distance GHS3 between the third pixel PX3 and the seam portion SM in the first direction DR1, a minimum distance GHS4 between the fourth pixel PX4 and the seam portion SM in the first direction DR1, and the width GSM1 of the seam portion SM in the first direction DR1.

In one or more embodiments, the minimum distance G34 between the third pixel PX3 and the fourth pixel PX4 neighboring to each other in the first direction DR1, the third horizontal spaced distance GH3, and the fourth horizontal spaced distance GH4 may be substantially the same as or similar to each other. As an example, the minimum distance GHS3 between the third pixel PX3 and the seam portion SM in the first direction DR1 may be less than the third horizontal spaced distance GH3, and the minimum distance GHS4 between the fourth pixel PX4 and the seam portion SM in the first direction DR1 may be less than the fourth horizontal spaced distance GH4. In addition, the width GSM1 of the seam portion SM in the first direction DR1 may be less than the third horizontal spaced distance GH3 or the fourth horizontal spaced distance GH4.

A minimum distance between the first pixels PX1 neighboring to each other in the second direction DR2 may be defined as a first vertical spaced distance GV1, and a minimum distance between the third pixels PX3 neighboring to each other in the second direction DR2 may be defined as a third vertical spaced distance GV3. The first vertical spaced distance GV1 and the third vertical spaced distance GV3 may be substantially the same as each other.

The seam portion SM may be located between the first pixel PX1 and the third pixel PX3 neighboring to each other in the second direction DR2. A minimum distance G13 between the first pixel PX1 and the third pixel PX3 neighboring to each other in the second direction DR2 may be the sum of a minimum distance GVS1 between the first pixel PX1 and the seam portion SM in the second direction DR2, a minimum distance GVS3 between the third pixel PX3 and the seam portion SM in the second direction DR2, and a width GSM2 of the seam portion SM in the second direction DR2.

In one or more embodiments, the minimum distance G13 between the first pixel PX1 and the third pixel PX3 neighboring to each other in the second direction DR2, the first vertical spaced distance GV1, and the third vertical spaced distance GV3 may be substantially the same as or similar to each other. As an example, the minimum distance GVS1 between the first pixel PX1 and the seam portion SM in the second direction DR2 may be less than the first vertical spaced distance GV1, and the minimum distance GVS3 between the third pixel PX3 and the seam portion SM in the second direction DR2 may be less than the third vertical spaced distance GV3. In addition, the width GSM2 of the seam portion SM in the second direction DR2 may be less than the first vertical spaced distance GV1 or the third vertical spaced distance GV3.

A minimum distance between the second pixels PX2 neighboring to each other in the second direction DR2 may be defined as a second vertical spaced distance GV2, and a minimum distance between the fourth pixels PX4 neighboring to each other in the second direction DR2 may be defined as a fourth vertical spaced distance GV4. The second vertical spaced distance GV2 and the fourth vertical spaced distance GV4 may be substantially the same as each other.

The seam portion SM may be located between the second pixel PX2 and the fourth pixel PX4 neighboring to each other in the second direction DR2. A minimum distance G24 between the second pixel PX2 and the fourth pixel PX4 neighboring to each other in the second direction DR2 may be the sum of a minimum distance GVS2 between the second pixel PX2 and the seam portion SM in the second direction DR2, a minimum distance GVS4 between the fourth pixel PX4 and the seam portion SM in the second direction DR2, and the width GSM2 of the seam portion SM in the second direction DR2.

In one or more embodiments, the minimum distance G24 between the second pixel PX2 and the fourth pixel PX4 neighboring to each other in the second direction DR2, the second vertical spaced distance GV2, and the fourth vertical spaced distance GV4 may be substantially the same as or similar to each other. As an example, the minimum distance GVS2 between the second pixel PX2 and the seam portion SM in the second direction DR2 may be less than the second vertical spaced distance GV2, and the minimum distance GVS4 between the fourth pixel PX4 and the seam portion SM in the second direction DR2 may be less than the fourth vertical spaced distance GV4. In addition, the width GSM2 of the seam portion SM in the second direction DR2 may be less than the second vertical spaced distance GV2 or the fourth vertical spaced distance GV4.

As illustrated in FIG. 18, to reduce or prevent visibility of the seam portion SM between images displayed by the display devices 10, a minimum distance between pixels of the display devices 10 neighboring to each other may be substantially the same as a minimum distance between pixels of each of the display devices 10.

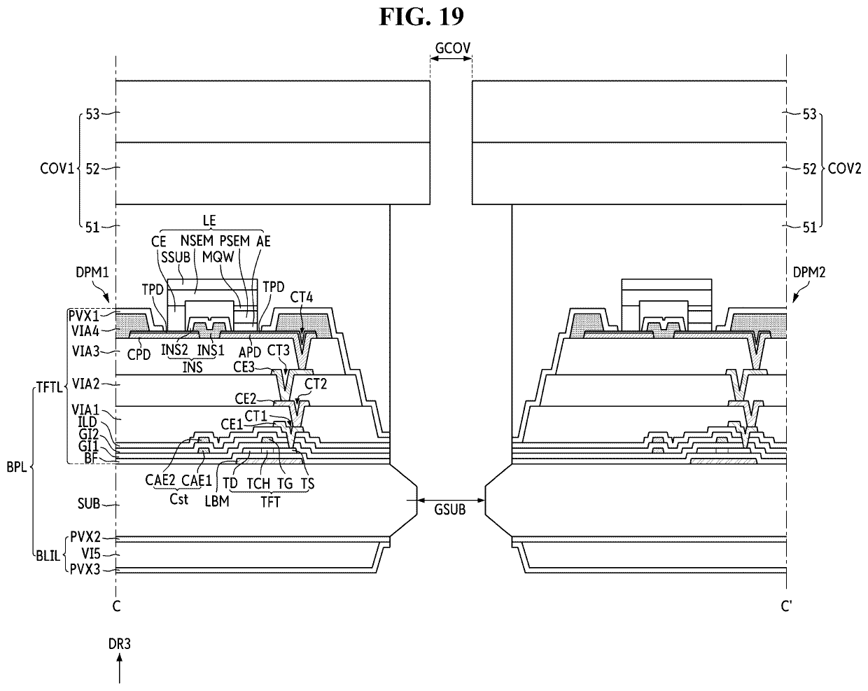

FIG. 19 is a cross-sectional view illustrating the tiled display device according to one or more embodiments. For example, FIG. 19 illustrates one or more embodiments of a cross section of a portion of the tiled display device TDIS taken along the line C-C′ of FIG. 18.

Referring to FIG. 19, the first display device 11 includes a first display module DPM1 and a first front cover COV1. The second display device 12 includes a second display module DPM2 and a second front cover COV2.

Each of the first display module DPM1 and the second display module DPM2 includes a backplane layer BPL and light-emitting elements LE. The backplane layer BPL of each of the first display module DPM1 and the second display module DPM2 may include an insulating layer INS located between a first pad electrode APD and a second pad electrode CPD and including an organic layer INS1 and an inorganic layer INS2.

A distance GSUB between a substrate SUB of the first display device 11 and a substrate SUB of the second display device 12 may be greater than a distance GCOV between the first front cover COV1 and the second front cover COV2.

Each of the first front cover COV1 and the second front cover COV2 may include an adhesive member 51, a light-transmissivity-adjusting layer 52 located on the adhesive member 51, and an anti-glare layer 53 located on the light-transmissivity-adjusting layer 52.

The adhesive member 51 of the first front cover COV1 serves to adhere the first display module DPM1 and the first front cover COV1 to each other. The adhesive member 51 of the second front cover COV2 serves to adhere the second display module DPM2 and the second front cover COV2 to each other. The adhesive member 51 may be a transparent adhesive member capable of transmitting light. For example, the adhesive member 51 may be an optically clear adhesive film or an optically clear resin.

The light-transmissivity-adjusting layer 52 may be designed to reduce transmissivity of external light or light reflected from the first display module DPM1 and the second display module DPM2. For this reason, visibility of the distance GSUB between the substrate SUB of the first display module DPM1 and the substrate SUB of the second display module DPM2 may be reduced or prevented. In one or more embodiments, the light-transmissivity-adjusting layer 52 may include a phase retardation layer.

The anti-glare layer 53 may be designed to diffusely reflect external light to reduce or prevent deterioration of visibility of an image occurring because the external light is reflected as it is. A contrast ratio of images displayed by the first display device 10 and the second display device 20 may be increased due to the anti-glare layer 53. In one or more embodiments, the anti-glare layer 53 may include a polarizing plate.

In concluding the detailed description, those skilled in the art will appreciate that many variations and modifications can be made to the embodiments without substantially departing from aspects of the present disclosure. Therefore, the disclosed embodiments are used in a generic and descriptive sense only and not for purposes of limitation.

What is claimed is:

1. An electronic device comprising a display device comprising:
a substrate comprising a sub-pixel area;
a first pad electrode and a second pad electrode above a first surface of the substrate, and spaced apart from each other in the sub-pixel area;
an insulating layer between the first pad electrode and the second pad electrode, covering an end of the first pad electrode facing the second pad electrode, covering an end of the second pad electrode facing the first pad electrode, and comprising an organic layer, and an inorganic layer above the organic layer; and
a light-emitting element above the first pad electrode, the second pad electrode, and the insulating layer, and electrically connected between the first pad electrode and the second pad electrode.

2. The electronic device of claim 1, wherein the organic layer covers the end of the first pad electrode and the end of the second pad electrode, and
wherein the inorganic layer completely covers the organic layer.

3. The electronic device of claim 1, further comprising:
a planarization layer at an edge of the sub-pixel area above the first surface of the substrate, and defining an opening at an area where the light-emitting element is located; and
a passivation layer above the planarization layer.

4. The electronic device of claim 3, wherein the planarization layer and the passivation layer cover another end of the first pad electrode, and another end of the second pad electrode.

5. The electronic device of claim 3, wherein the organic layer and the planarization layer comprise a same organic insulating material, and
wherein a height of the organic layer is lower than a height of the planarization layer.

6. The electronic device of claim 3, wherein the inorganic layer and the passivation layer comprise a same inorganic insulating material.

7. The electronic device of claim 3, wherein the inorganic layer completely covers the organic layer, and
wherein the passivation layer completely covers the planarization layer.

8. The electronic device of claim 1, wherein the light-emitting element comprises:
a first portion above the first pad electrode;
a second portion above the second pad electrode; and
a third portion above the insulating layer, and connecting the first portion and the second portion.

9. The electronic device of claim 8, wherein a thickness of the third portion is less than a thickness of the first portion and less than a thickness of the second portion.

10. The electronic device of claim 1, further comprising a back-side line below a second surface of the substrate.

11. A method for fabricating a display device, comprising:
arranging a first pad electrode and a second pad electrode in a sub-pixel area above a substrate;
arranging an insulating layer covering an end of the first pad electrode and an end of the second pad electrode, and comprising an organic layer between the first pad electrode and the second pad electrode, and an inorganic layer above the organic layer; and
arranging a light-emitting element above the first pad electrode, the second pad electrode, and the insulating layer so as to be electrically connected to the first pad electrode and the second pad electrode.

12. The method for fabricating the display device of claim 11, wherein the organic layer covers the end of the first pad electrode and the end of the second pad electrode.

13. The method for fabricating the display device of claim 11, further comprising arranging a planarization layer at an edge of the sub-pixel area.

14. The method for fabricating the display device of claim 13, wherein the organic layer is at a lower height than the planarization layer.

15. The method for fabricating the display device of claim 13, further comprising arranging a passivation layer covering the planarization layer.

16. A tiled display device comprising:
display devices, at least one of the display devices comprising:
a substrate comprising a sub-pixel area;
a first pad electrode and a second pad electrode above a first surface of the substrate, and spaced apart from each other in the sub-pixel area;
an insulating layer between the first pad electrode and the second pad electrode, covering an end of the first pad electrode facing the second pad electrode, covering an end of the second pad electrode facing the first pad electrode, and comprising an organic layer, and an inorganic layer above the organic layer; and
a light-emitting element above the first pad electrode, the second pad electrode, and the insulating layer, and electrically connected between the first pad electrode and the second pad electrode.

17. The tiled display device of claim 16, wherein the organic layer covers the end of the first pad electrode and the end of the second pad electrode, and
wherein the inorganic layer completely covers the organic layer.

18. The tiled display device of claim 16, wherein the at least one of the display devices further comprises:
a planarization layer at an edge of the sub-pixel area above the first surface of the substrate, and defining an opening at an area where the light-emitting element is located; and
a passivation layer above the planarization layer.

19. The tiled display device of claim 18, wherein the organic layer and the planarization layer comprise a same organic insulating material, and
wherein a height of the organic layer is lower than a height of the planarization layer.

20. The tiled display device of claim 16, wherein the at least one of the display devices further comprises a back-side line below a second surface of the substrate.
